(19) United States
(12) Patent Application Publication
(10) Pub. No.: US 2024/0249173 A1
(43) Pub. Date: Jul. 25, 2024

(54) METHODS AND DEVICES FOR CONTINUOUS OPERATION OF A COLD-ATOM DEVICE USING A SEPARATE RESERVOIR ARRAY

(71) Applicant: Atom Computing Inc., Berkeley, CA (US)

(72) Inventors: Matthew NORCIA, Boulder, CO (US); Benjamin BLOOM, Berkeley, CA (US); Hyosub KIM, Boulder, CO (US); Mickey McDONALD, Boulder, CO (US); William CAIRNCROSS, Boulder, CO (US)

(21) Appl. No.: 18/415,394

(22) Filed: Jan. 17, 2024

Related U.S. Application Data
(63) Continuation of application No. PCT/US2023/075948, filed on Oct. 4, 2023.
(60) Provisional application No. 63/413,203, filed on Oct. 4, 2022.

(51) Int. Cl. G06N 10/20; G06F 30/20

(52) U.S. Cl. CPC G06N 10/20; G06F 30/20

(57) ABSTRACT

Systems and method for performing continuous, non-classical computation, may include: loading a plurality of atoms into a reservoir array; transferring a first subset of the plurality of atoms from the reservoir array into a science array; performing a first non-classical computation using at least some of the first subset; determining an atomic loss number representing a difference between (i) a number of atoms in the first subset and (ii) a number of atoms in a remaining subset of the first subset that remain in the science array following the performing of the first non-classical computation; transferring a second subset of the plurality of atoms from the reservoir array into the science array; reloading the reservoir array with additional atoms; and performing a second non-classical computation using at least some of one or both of the remaining subset and the second subset.

### CROSS-REFERENCE

This application is a continuation of International Application No. PCT/US2023/075948, filed Oct. 4, 2023, which claims the benefit of U.S. Provisional Application Ser. No. 63/413,203, filed Oct. 4, 2022, each of which is incorporated herein by reference in its entirety.

### BACKGROUND

Quantum computers typically make use of quantum-mechanical phenomena, such as superposition and entanglement, to perform operations on data. Quantum computers may be different from digital electronic computers based on transistors. For instance, whereas digital computers require data to be encoded into binary digits (bits), each of which is always in one of two definite states (0 or 1), quantum computation uses quantum bits (qubits), which can be in superpositions of states.

In neutral-atom quantum computers or simulation devices, qubits may be encoded in optically trapped atoms. Because the optical traps may be relatively shallow, atoms may become lost due to collisions with residual background gas, to leakage into un-trapped or otherwise undesirable internal states, or due to heating associated with laser interactions or other processes. In quantum computers or simulation devices, typically a subset of the total optical trapping array (referred to herein as “science region”) may be filled in order to perform calculations or simulations. In order to perform continuous or repeated calculations, it may be important to reload atoms into the optical traps.

### SUMMARY

The present disclosure describes methods and systems that, in some embodiments, replenish a science region from a reservoir where the science and reservoir regions are distinct, so that the reservoir can be refilled without disturbing atoms within the science region. This allows for continuous or quasi-continuous (beyond the lifetime of the atoms within the science region) occupation and coherent operations within the science region.

In an aspect, the present application provides a method for preparing a sample of atoms. The method may comprise: (a) trapping a plurality of atoms into a science array, wherein the science array comprises a first plurality of spatially distinct optical trapping sites; (b) transferring at least one atom from a reservoir array into the science array to increase a fill factor of the science array, wherein the reservoir array comprises a second plurality of spatially distinct optical trapping sites; and (c) transferring at least one atom into the reservoir array to increase a fill factor of the reservoir array, wherein the transferring in (c) is performed at least partially during the transferring the at least one atom from the reservoir array into the science array in (b).

In some embodiments, the method further comprises repeating (b) and (c) a number of times to maintain a fill factor in the science array. In some embodiments, the method further comprises performing a sensing application using the at least the first subset of the plurality of atoms. In some embodiments, the method further comprises performing a time-keeping operation using the at least the first subset of the plurality of atoms. In some embodiments, the method further comprises performing a computation using the at least the first subset of the plurality of atoms. In some embodiments, the computation is a non-classical computation, and wherein (c) is performed substantially without stopping the non-classical computation. In some embodiments, performing the non-classical computation includes: applying electromagnetic energy to one or more atoms of the first subset of the plurality of atoms in the science array, thereby inducing the one or more atoms to adopt one or more superposition states of a first atomic state and at least a second atomic state that is different from the first atomic state; quantum mechanically entangling at least one of the one or more atoms in the one or more superposition states with at least another atom of the first subset of the plurality of atoms in the science array; and measuring the one or more superposition states to obtain a non-classical result. In some embodiments, the first atomic state and the second atomic states comprise first nuclear spin states and second nuclear spin states of a nucleus comprising a nuclear spin greater than or equal to ½. In some embodiments, the one or more atoms of the first subset of the plurality of atoms in the one or more superposition states and the at least another atom of the first subset of the plurality of atoms in the science array are quantum mechanically entangled with a coherence lifetime of at least 1 second.

In some embodiments, the plurality of atoms comprises neutral atoms. In some embodiments, the plurality of atoms comprises a Group II element. In some embodiments, the plurality of atoms comprises Scandium. In some embodiments, the plurality of atoms comprises a Group II like element. In some embodiments, the plurality of atoms comprises an atom with two-valence electrons. In some embodiments, the plurality of atoms comprises Ytterbium.

In some embodiments, the plurality of atoms comprises a temperature of at most 10 microkelvin (μK). In some embodiments, one or both of (i) loading the plurality of atoms into the reservoir or (ii) reloading the reservoir array with the additional atoms, is performed using one or both of a moving optical trap or an optical tweezer. In some embodiments, the science array is distinct from the reservoir array. In some embodiments, the science array is physically separated from the reservoir array, optionally, wherein the physical separation is more than 10 cm.

In some embodiments, subsequent to (a), the method further comprises determining an atomic loss number representing a difference between (i) a number of atoms in the plurality of atoms trapped into the science array and (ii) a number of atoms in a remaining subset of the plurality of atoms trapped into the science array that remain in the science array following the performing of at least some of the non-classical computation. In some embodiments, the at least one atom transferred from the reservoir array into the science array comprise a number of atoms equal to at least the atomic loss number. In some embodiments, determining the atomic loss number is based on imaging across an imaging axis to determine which sites of the second plurality of spatially distinct optical trapping sites of the science array are occupied. In some embodiments, the science array is physically separated from the reservoir array parallel to the imaging axis; and one or both of (i) transferring the first subset of the plurality of atoms from the reservoir array into the science array or (ii) transferring the second subset of the plurality of atoms from the reservoir array into the science array, is performed using one or both of a moving optical trap or an optical tweezer.

In some embodiments, both the science array and the reservoir array are two-dimensional. In some embodiments, both the science array and the reservoir array are three-dimensional. In some embodiments, the science array has a different number of dimensions than the reservoir array. In some embodiments, one or both of the science array or the reservoir array are formed using either light or non-optical electromagnetic fields. In some embodiments, a second number of sites in the second plurality of optical trapping sites is equal to a first number of sites in the first plurality of optical trapping sites. In some embodiments, a second number of sites in the second plurality of optical trapping sites is greater than a first number of sites in the first plurality of optical trapping sites.

In some embodiments, transferring the at least one atom from the reservoir array into the science array comprises: transferring a first number of atoms from the reservoir array to one or more intermediate arrays, wherein the first number of atoms is at least a subset of the at least one atom; and transferring a second number of atoms from the one or more intermediate arrays to the science array, wherein the second number of atoms is at most the first number of atoms. In some embodiments, the one or more intermediate arrays includes at least two intermediate arrays; and at least the second number of atoms are transferred between the at least two intermediate arrays (i) after the first number of atoms are transferred to the at least two intermediate arrays from the reservoir array and (ii) before the second number of atoms are transferred from the at least two intermediate arrays to the science array.

In some embodiments, the method further comprises rearranging, within the science array, positions among the first plurality of spatially distinct optical trapping sites of at least some of one or both of (i) the plurality of atoms in the science array or (ii) the at least one atom in aid science array. In some embodiments, the science array is associated with a first spatial light modulator and the reservoir array is associated with a second spatial light modulator. In some embodiments, the at least one atom that is transferred from the reservoir array into the science array is in a dark state, a clock state, or another state forbidden by selection rules from an optical excitation used for the transferring. In some embodiments, the transfer of the at least one atom that is from the reservoir array into the science array is a long-range transfer. In some embodiments, the plurality of atoms are qubits.

In another aspect, the present disclosure provides a method for preparing a sample of atoms. The method may comprise: (a) trapping a plurality of atoms into a science array, wherein the science array comprises a first plurality of spatially distinct optical trapping sites; (b) inducing at least a first subset of the plurality of atoms to adopt one or more superposition states at least a first subset of the plurality of atoms in the science array; and (c) transferring at least one atom from a reservoir array into the science array, wherein the reservoir array comprises a second plurality of spatially distinct optical trapping sites, and wherein the transferring in (c) is performed substantially without decoherence of the superposition state.

In some embodiments, the method further comprises repeating (c) a number of times to maintain a fill factor in the science array. In some embodiments, (b) comprises performing a sensing application using the at least the first subset of the plurality of atoms. In some embodiments, (b) comprises performing a time-keeping operation using the at least the first subset of the plurality of atoms. In some embodiments, (b) comprises performing a computation using the at least the first subset of the plurality of atoms. In some embodiments, the computation is a non-classical computation, and wherein (c) is performed substantially without stopping the non-classical computation. In some embodiments, performing the non-classical computation includes: applying electromagnetic energy to one or more atoms of the first subset of the plurality of atoms in the science array, thereby inducing the one or more atoms to adopt one or more superposition states of a first atomic state and at least a second atomic state that is different from the first atomic state; quantum mechanically entangling at least one of the one or more atoms in the one or more superposition states with at least another atom of the first subset of the plurality of atoms in the science array; and measuring the one or more superposition states to obtain a non-classical result. In some embodiments, the first atomic state and the second atomic states comprise first nuclear spin states and second nuclear spin states of a nucleus comprising a nuclear spin greater than or equal to ½. In some embodiments, the one or more atoms of the first subset of the plurality of atoms in the one or more superposition states and the at least another atom of the first subset of the plurality of atoms in the science array are quantum mechanically entangled with a coherence lifetime of at least 1 second.

In some embodiments, the method further comprises loading one or more atoms into the reservoir array that comprises the second plurality of spatially distinct optical trapping sites. In some embodiments, the plurality of atoms comprises neutral atoms. In some embodiments, the plurality of atoms comprises a Group II element. In some embodiments, the plurality of atoms comprises Scandium. In some embodiments, the plurality of atoms comprises a Group II like element. In some embodiments, the plurality of atoms comprises an atom with two-valence electrons. In some embodiments, the plurality of atoms comprises Ytterbium. In some embodiments, the plurality of atoms comprises a temperature of at most 10 microkelvin (μK).

In some embodiments, one or both of (i) loading the plurality of atoms into the reservoir or (ii) reloading the reservoir array with the additional atoms, is performed using one or both of a moving optical trap or an optical tweezer. In some embodiments, the science array is distinct from the reservoir array. In some embodiments, the science array is physically separated from the reservoir array, optionally, wherein the physical separation is more than 10 cm.

In some embodiments, subsequent to (a), the method further comprises determining an atomic loss number representing a difference between (i) a number of atoms in the plurality of atoms trapped into the science array and (ii) a number of atoms in a remaining subset of the plurality of atoms trapped into the science array that remain in the science array following the performing of at least some of the non-classical computation.

In some embodiments, the at least one atom transferred from the reservoir array into the science array comprise a number of atoms equal to at least the atomic loss number. In some embodiments, determining the atomic loss number is based on imaging across an imaging axis to determine which sites of the second plurality of spatially distinct optical trapping sites of the science array are occupied. In some embodiments, the science array is physically separated from the reservoir array parallel to the imaging axis, and one or both of (i) transferring the first subset of the plurality of atoms from the reservoir array into the science array or (ii) transferring the second subset of the plurality of atoms from the reservoir array into the science array, is performed using one or both of a moving optical trap or an optical tweezer.

In some embodiments, both the science array and the reservoir array are two-dimensional. In some embodiments, both the science array and the reservoir array are three-dimensional. In some embodiments, the science array has a different number of dimensions than the reservoir array. In some embodiments, one or both of the science array or the reservoir array are formed using either light or non-optical electromagnetic fields. In some embodiments, a second number of sites in the second plurality of optical trapping sites is equal to a first number of sites in the first plurality of optical trapping sites. In some embodiments, a second number of sites in the second plurality of optical trapping sites is greater than a first number of sites in the first plurality of optical trapping sites.

In some embodiments, transferring the at least one atom from the reservoir array into the science array comprises: transferring a first number of atoms from the reservoir array to one or more intermediate arrays, wherein the first number of atoms is at least a subset of the at least one atom; and transferring a second number of atoms from the one or more intermediate arrays to the science array, wherein the second number of atoms is at most the first number of atoms.

In some embodiments, the one or more intermediate arrays includes at least two intermediate arrays; and at least the second number of atoms are transferred between the at least two intermediate arrays (i) after the first number of atoms are transferred to the at least two intermediate arrays from the reservoir array and (ii) before the second number of atoms are transferred from the at least two intermediate arrays to the science array.

In some embodiments, the method further comprises rearranging, within the science array, positions among the first plurality of spatially distinct optical trapping sites of at least some of one or both of (i) the plurality of atoms in the science array or (ii) the at least one atom in aid science array. In some embodiments, the science array is associated with a first spatial light modulator and the reservoir array is associated with a second spatial light modulator. In some embodiments, the at least one atom that is transferred from the reservoir array into the science array is in a dark state, a clock state, or another state forbidden by selection rules from an optical excitation used for the transferring. In some embodiments, the transfer of the at least one atom that is from the reservoir array into the science array is a long-range transfer. In some embodiments, the plurality of atoms are qubits.

In another aspect, the present disclosure provides a system for preparing a sample of atoms, the system comprising: one or more atom transfer units configured to implement the method of any aspect or embodiment herein.

In another aspect, the present disclosure provides a system for preparing a sample of atoms. The system may comprise: one or more optical trapping units configured to obtain: a science array that comprises a first plurality of spatially distinct optical trapping sites, wherein the science array comprises a first plurality of atoms trapped in the first plurality of spatially distinct optical trapping sites, and a reservoir array that comprises a second plurality of spatially distinct optical trapping sites, wherein the reservoir array comprises a second plurality of atoms trapped in the second plurality of spatially distinct optical trapping sites; one or more atom movement units configured to: (a) transfer at least one atom from a reservoir array into the science array to increase a fill factor of the science array; and (b) transfer at least one atom into the reservoir array to increase a fill factor of the reservoir array, wherein the transferring in (b) is performed at least partially during the transferring the at least one atom from the reservoir array into the science array in (a).

In another aspect, the present disclosure provides a system for preparing a sample of atoms. The system may comprise: one or more optical trapping units configured to obtain: a science array that comprises a first plurality of spatially distinct optical trapping sites, wherein the science array comprises a first plurality of atoms trapped in the first plurality of spatially distinct optical trapping sites, and a reservoir array that comprises a second plurality of spatially distinct optical trapping sites, wherein the reservoir array comprises a second plurality of atoms trapped in the second plurality of spatially distinct optical trapping sites; one or more electromagnetic delivery units configured induce at least a first subset of the plurality of atoms to adopt one or more superposition states at least a first subset of the plurality of atoms in the science array; and one or more atom movement units configured to transfer at least one atom of the second plurality of atoms from the reservoir array into the science array, wherein the transferring is performed substantially without decoherence of the superposition state.

In another aspect, the present disclosure provides a method for performing continuous, non-classical computation. The method may comprise: loading a plurality of atoms into a reservoir array that includes a first plurality of spatially distinct optical trapping sites, the first plurality of optical trapping sites configured to trap the plurality of atoms, wherein the plurality of atoms are qubits; transferring a first subset of the plurality of atoms from the reservoir array into a science array that includes a second plurality of spatially distinct optical trapping sites, the second plurality of optical trapping sites configured to trap the plurality of atoms; performing a first non-classical computation using at least some of the first subset of the plurality of atoms in the science array; determining an atomic loss number representing a difference between (i) a number of atoms in the first subset of the plurality of atoms and (ii) a number of atoms in a remaining subset of the first subset of the plurality of atoms that remain in the science array following the performing of the first non-classical computation, and transferring a second subset of the plurality of atoms from the reservoir array into the science array, wherein the second subset of the plurality of atoms includes at least a number of atoms equal to the atomic loss number; reloading the reservoir array with additional atoms that are qubits; and performing a second non-classical computation using at least some of one or both of (i) the remaining subset of the first subset of the plurality of atoms and (ii) the second subset of the plurality of atoms.

In some embodiments, performing the first non-classical computation includes: applying electromagnetic energy to one or more atoms of the first subset of the plurality of atoms in the science array, thereby inducing the one or more atoms to adopt one or more superposition states of a first atomic state and at least a second atomic state that is different from the first atomic state; quantum mechanically entangling at least one of the one or more atoms in the one or more superposition states with at least another atom of the first subset of the plurality of atoms in the science array; and measuring the one or more superposition states to obtain a first non-classical result. In some embodiments, the first and second atomic states comprise first and second nuclear spin states of a nucleus comprising a nuclear spin greater than 2. In some embodiments, the at least a subset of the at least one atom in the one or more superposition states and the at least another atom of the first subset of the plurality of atoms in the science array are quantum mechanically entangled with a coherence lifetime of at least 1 second.

In some embodiments, the plurality of atoms and the additional atoms both comprise neutral atoms. In some embodiments, the plurality of atoms and the additional atoms both comprise a Group II element. In some embodiments, the plurality of atoms and the additional atoms both comprise a temperature of at most 10 microkelvin (μK). In some embodiments, one or both of (i) loading the plurality of atoms into the reservoir or (ii) reloading the reservoir array with the additional atoms, is performed using one or both of a moving optical trap or an optical tweezer. In some embodiments, the science array is physically separated from the reservoir array. In some embodiments, determining the atomic loss number is based on imaging across an imaging axis to determine which sites of the second plurality of spatially distinct optical trapping sites of the science array are occupied. In some embodiments, the science array is physically separated from the reservoir array parallel to the imaging axis; and one or both of (i) transferring the first subset of the plurality of atoms from the reservoir array into the science array or (ii) transferring the second subset of the plurality of atoms from the reservoir array into the science array, is performed using one or both of a moving optical trap or an optical tweezer.

In some embodiments, both the science array and the reservoir array are two-dimensional. In some embodiments, both the science array and the reservoir array are three-dimensional. In some embodiments, the science array has a different number of dimensions than the reservoir array. In some embodiments, one or both of the science array or the reservoir array are formed using either light or non-optical electromagnetic fields. In some embodiments, a first number of sites in the first plurality of optical trapping sites is equal to a second number of sites in the second plurality of optical trapping sites. In some embodiments, a first number of sites in the first plurality of optical trapping sites is greater than a second number of sites in the second plurality of optical trapping sites. In some embodiments, transferring the first subset of the plurality of atoms from the reservoir array into a science array includes: transferring at least the first subset of the plurality of atoms from the reservoir array to one or more intermediate arrays; and transferring the first subset of the plurality of atoms from the one or more intermediate arrays to the science array. In some embodiments, the one or more intermediate arrays includes at least two arrays; and the at least the first subset of the plurality of atoms are transferred between the at least two arrays (i) after the at least the first subset of the plurality of atoms are transferred to the at least two arrays from the reservoir array and (ii) before the first subset of the plurality of atoms are transferred from the at least two arrays to the science array. In some embodiments, the method further comprises rearranging, within the science array, positions among the second plurality of spatially distinct optical trapping sites of at least some of one or both of (i) the remaining subset of the first subset of the plurality of atoms and (ii) the second subset of the plurality of atoms.

Another aspect of the present disclosure provides a system comprising one or more computer processors and computer memory coupled thereto. The computer memory comprises machine executable code that, upon execution by the one or more computer processors, implements any of the methods above or elsewhere herein.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure.

Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 shows a computer control system that is programmed or otherwise configured to implement methods provided herein.

FIG. 2 illustrates an example process for performing continuous, non-classical computation.

FIG. 3 illustrates an example method and system preparing a sample of atoms.

FIG. 4 illustrates another example method and system preparing a sample of atoms.

FIG. 5 illustrates another example method and system preparing a sample of atoms.

FIG. 6 illustrates data from an experiment relating to conditional reloading of ancilla qubits.

FIG. 7 illustrates experimental data demonstrating coherence during MOT loading.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Unless otherwise defined, all technical terms used herein have the same meaning as commonly understood by one of ordinary skill in the art to which this invention belongs. As used in this specification and the appended claims, the singular forms “a,” “an,” and “the” include plural references unless the context clearly dictates otherwise. Any reference to “or” herein is intended to encompass “and/or” unless otherwise stated.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than.” or “less than or equal to” applies to each of the numerical values in that series of numerical values. For example, less than or equal to 3, 2, or 1 is equivalent to less than or equal to 3, less than or equal to 2, or less than or equal to 1.

Where values are described as ranges, it will be understood that such disclosure includes the disclosure of all possible sub-ranges within such ranges, as well as specific numerical values that fall within such ranges irrespective of whether a specific numerical value or specific sub-range is expressly stated.

As used herein, like characters refer to like elements.

The term “about” or “approximately” may mean within an acceptable error range for the particular value, which will depend in part on how the value is measured or determined, e.g., the limitations of the measurement system. For example, “about” may mean within 1 or more than 1 standard deviation, per the practice in the art. Alternatively, “about” may mean a range of up to 20%, up to 10%, up to 5%, or up to 1% of a given value. Where particular values are described in the application and claims, unless otherwise stated the term “about” meaning within an acceptable error range for the particular value may be assumed.

As used herein, the terms “non-classical computation.” “non-classical procedure,” “non-classical operation,” any “non-classical computer” generally refer to any method or system for performing computational procedures outside of the paradigm of classical computing. A non-classical computation, non-classical procedure, non-classical operation, or non-classical computer may comprise a quantum computation, quantum procedure, quantum operation, or quantum computer.

As used herein, the terms “quantum computation,” “quantum procedure,” “quantum operation.” and “quantum computer” generally refer to any method or system for performing computations using quantum mechanical operations (such as unitary transformations or completely positive trace-preserving (CPTP) maps on quantum channels) on a Hilbert space represented by a quantum device. As such, quantum and classical (or digital) computation may be similar in the following aspect: both computations may comprise sequences of instructions performed on input information to then provide an output. Various paradigms of quantum computation may break the quantum operations down into sequences of basic quantum operations that affect a subset of qubits of the quantum device simultaneously. The quantum operations may be selected based on, for instance, their locality or their ease of physical implementation. A quantum procedure or computation may then consist of a sequence of such instructions that in various applications may represent different quantum evolutions on the quantum device. For example, procedures to compute or simulate quantum chemistry may represent the quantum states and the annihilation and creation operators of electron spin-orbitals by using qubits (such as two-level quantum systems) and a universal quantum gate set (such as the Hadamard, controlled-not (CNOT), and π/8 rotations) through the so-called Jordan-Wigner transformation or Bravyi-Kitaev transformation.

Additional examples of quantum procedures or computations may include procedures for optimization such as quantum approximate optimization algorithm (QAOA) or quantum minimum finding. QAOA may comprise performing rotations of single qubits and entangling gates of multiple qubits. In quantum adiabatic computation, the instructions may carry stochastic or non-stochastic paths of evolution of an initial quantum system to a final one.

Quantum-inspired procedures may include simulated annealing, parallel tempering, master equation solver, Monte Carlo procedures and the like. Quantum-classical or hybrid algorithms or procedures may comprise such procedures as variational quantum eigensolver (VQE) and the variational and adiabatically navigated quantum eigensolver (VanQver).

A quantum computer may comprise one or more adiabatic quantum computers, quantum gate arrays, one-way quantum computers, topological quantum computers, quantum Turing machines, quantum annealers, Ising solvers, or gate models of quantum computing.

As used herein, the term “adiabatic” refers to any process performed on a quantum mechanical system in which the parameters of the Hamiltonian are changed slowly in comparison to the natural timescale of evolution of the system.

As used herein, the term “non-adiabatic” refers to any process performed quantum mechanical system in which the parameters of the Hamiltonian are changed quickly in comparison to the natural timescale of evolution of the system or on a similar timescale as the natural timescale of evolution of the system.

The present disclosure describes methods and systems that, in some embodiments, replenish a science region from a reservoir where the science and reservoir regions are distinct, so that the reservoir can be refilled without disturbing atoms within the science region. This allows for continuous or quasi-continuous (beyond the lifetime of the atoms within the science region) occupation and coherent operations within the science region.

In neutral-atom quantum computers or simulation devices, qubits may be encoded in optically trapped atoms. Because the optical traps may be relatively shallow, atoms may become lost due to collisions with residual background gas, to leakage into un-trapped or otherwise undesirable internal states, or due to heating associated with laser interactions or other processes. In quantum computers or simulation devices, typically a subset of the total optical trapping array (referred to herein as “science region”) may be filled in order to perform calculations or simulations. In order to perform continuous or repeated calculations, it may be important to reload atoms into the optical traps.

Reloading the science region of quantum computers or simulation devices may be accomplished by overlapping the trapping array with a magneto-optical trap (MOT), which provides a dense, cold atomic gas, as well as the dissipation mechanism that can trap the atoms in the array. This process typically takes significant time, leads to loss of atoms already in the array, and only loads a fraction (often ˜50%) of the traps within the array. A fill factor of the array may be improved by imaging to determine which sites in the array are occupied, and then transferring atoms into the unfilled sites within the science region. This transfer may be performed using one or more moving optical traps, or tweezers. The trapping sites not within the science region form the reservoir region. In some embodiments, the reservoir region and the science region are two regions of the same array, in the sense that they are both formed using the same laser/optical elements. Further, the science and reservoir arrays may be refilled at the same time, in a manner that causes loss and decoherence of those atoms already in the science region. Systems and methods of the present disclosure may reduce loss of atoms, decoherence of atoms, or both during refilling processes.

### Example Processes for Performing Continuous, Non-Classical Computations

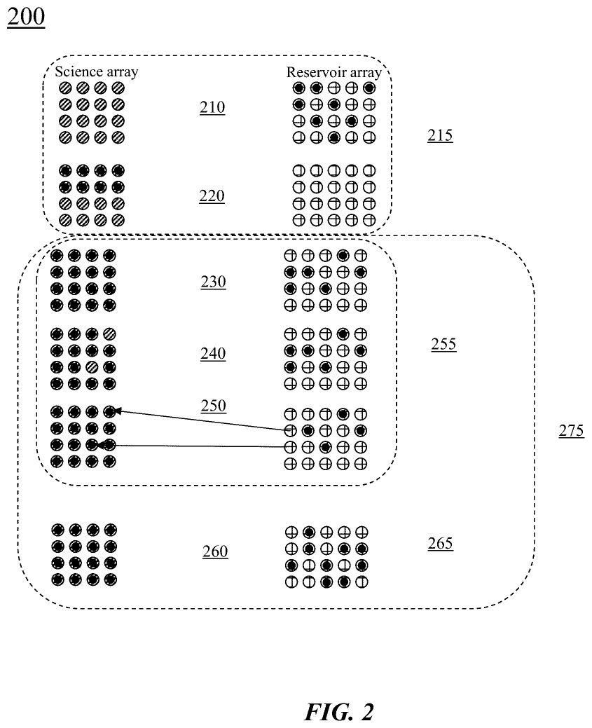

FIG. 2 illustrates an example process 200 for performing continuous, non-classical computation. In some examples, the process 200 may be implemented with the science region and the reservoir region being sufficiently distinct to enable loading of the reservoir region with sufficiently low disturbance of atoms within the science region. One way to accomplish this is for the reservoir and science regions to not be sub-regions of the same array, but rather to be distinct arrays in the sense that they may be formed using different lasers or different optical elements. Further, in some embodiments, the reservoir may be loaded from a third “transport” array, rather than from a MOT. This last technique may eliminate a use for near-resonant light, and so may allow for continuous coherent operations to be performed during the reloading process.

At a high level, the process 200 may comprise: loading a reservoir array, transferring atoms to a science array from the reservoir array, performing a computation/simulation using the science array, atomic loss occurring in the science array, refilling the science array from the reservoir array, and reloading the reservoir array. A science array may comprise atoms that are actively being used for the application (e.g., quantum computing, optical clocks, sensing, or any other application disclosed herein). A science array in a quantum computer may comprise data qubits and ancilla qubits. A reservoir array may comprise atoms that are not actively in use but which may be used at a later time to replace atoms lost from the science array, e.g., a lost ancilla qubit from a quantum computer.

In some cases, the process 200 may begin with both the reservoir array and the science array being empty. Once atoms are loaded into the reservoir array, the atoms in the reservoir may then be imaged. In some examples, at least some of the atoms in the reservoir array may then transferred into the science array (for example using optical tweezers). The reservoir array can be reloaded to achieve a full or fuller reservoir array and enable further transfer of more atoms from the reservoir array into the science array. Once the science array is fully occupied (or occupied to a desired/predetermined amount), the computation/simulation may begin.

During the computation/simulation, the science array may be periodically imaged to determine if and where atom loss has occurred. If an atom has been lost from a site in the science array, an atom from the reservoir array may be transferred to fill the site. This may continue provided there are sufficient atoms in the reservoir array. When there are not, new atoms may be loaded into the reservoir array, and the process continues. As illustrated in FIG. 2, the process 200 may be iterative or repetitive in some examples, with potential repetition of one or more operations of the process 200.

FIG. 2 shows an example method and system for performing continuous, non-classical computations. The method 200 may comprise an operation 210. Operation 210 may comprise loading a plurality of atoms into a reservoir array that includes a first plurality of spatially distinct optical trapping sites. The first plurality of optical trapping sites may be configured to trap the plurality of atoms. In some cases, the plurality of atoms are qubits in a non-classical computational system, such as a quantum computer, a quantum annealer, etc. In some cases, the plurality of atoms comprises atoms in an atomic clock.

The method 200 may comprise an operation 220. Operation 220 may comprise transferring a first subset of the plurality of atoms from the reservoir array into a science array. The science array may include a second plurality of spatially distinct optical trapping sites. The second plurality of optical trapping sites may be configured to trap a plurality of atoms.

In some cases, at operation 215, operations 210 and 220 may be repeated a number of times. The operations may be repeated until a science array comprises a sufficient fill factor for quantum computation, quantum simulation, clock operations, metrology operations, sensing operations, etc.

The method 200 may comprise an operation 230. Operation 230 may comprise performing a first application using at least some of the first subset of the plurality of atoms in the science array. The application may be quantum computation, quantum simulation, clock operations, metrology operations, sensing operations, etc.

The method 200 may comprise an operation 240. Operation 240 may comprise determining an atomic loss in one or more of the arrays. The operation may comprise determining an atomic loss number representing a difference between (i) a number of atoms in the first subset of the plurality of atoms and (ii) a number of atoms in a remaining subset of the first subset of the plurality of atoms that remain in the science array following the performing of the first non-classical computation. Atom loss may occur due to collisions with residual background gas, to leakage into un-trapped or otherwise undesirable internal states, due to heating associated with laser interactions, or other processes.

The method 200 may comprise an operation 250. Operation 250 may comprise transferring a second subset of the plurality of atoms from the reservoir array into the science array. Operation 250 may comprise a reloading operation. In some cases, the second subset of the plurality of atoms includes at least a number of atoms equal to the atomic loss number. In some cases, the second subset of the plurality of atoms includes a number of atoms less than the atomic loss number. The second subset may be transferred substantially without loss of a coherence of the plurality of atoms in the science array. The second subset may be transferred substantially without stopping an application in the science array.

In some cases, at operation 255, operations 230, 240, and 250 may be repeated a number of times. The operations may be repeated until a quantum computation, quantum simulation, clock operation, metrology operation, etc. is complete. The operations may be repeated while there are atoms in a reservoir to be filed into the science array.

The method 200 may comprise an operation 260. Operation 260 may comprise reloading the reservoir array with additional atoms. The reservoir may be reloaded from an atom source. The atom source may be cooled atom source. In some examples, reservoir regions may be filled from a magneto-optical trap (MOT), from an atomic beam, from a thermal atomic gas, from another optical or other form of electromagnetic trap, or from any other source of atoms. In some examples, the initial loading of the science region may be direct (from any atomic source other than the reservoir array), from the reservoir array, or from a separate reservoir array than the one used for replenishing. In some examples, the reservoir region may be smaller, larger, or the same size/number of sites as the science region and similar techniques may be used to maintain an arbitrary number of atoms within each site of the science array.

In some cases, at operation 265, operation 260 may be repeated a number of times. Operation 260 may be refilled a number of times to fill a reservoir array. The operation may be repeated such that an application in operation 230 may be performed continuously.

In some cases, at operation 275, operations 255 and 265 may be both be repeated in order to maintain a fill factor in the science array. In some cases, the method may comprise performing a second non-classical computation using at least some of one or both of (i) the remaining subset of the first subset of the plurality of atoms and (ii) the second subset of the plurality of atoms.

The present disclosure comprises various sub-operations of the method 200. For example, one or more of the operations of the method 200 may be remove. For example, one or more of the operations of the method 200 may be repeated.

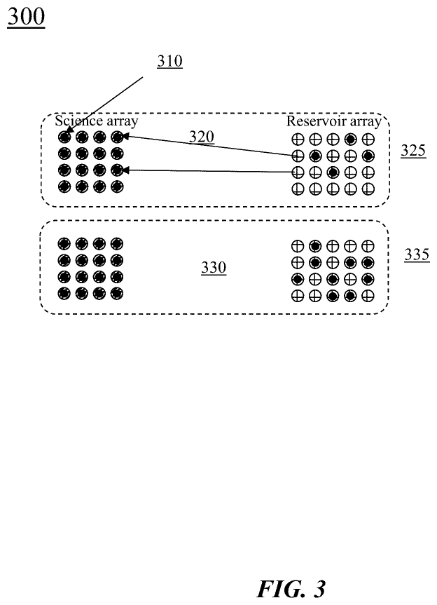

FIG. 3 shows an example method and system preparing a sample of atoms. The method 300 may comprise an operation 310. The operation 310 may comprise trapping a plurality of atoms into a science array, wherein the science array comprises a first plurality of spatially distinct optical trapping sites.

The method 300 may comprise an operation 320. The operation 320 may comprise transferring at least one atom from a reservoir array into the science array to increase a fill factor of the science array, wherein the reservoir array comprises a second plurality of spatially distinct optical trapping sites.

Operation 320 may comprise an embodiment, variation, or example of operation 220 of method 200. For example, the method 300 may comprise an operation 220. Operation 220 may comprise transferring a first subset of the plurality of atoms from the reservoir array into a science array. The science array may include a plurality of spatially distinct optical trapping sites from the reservoir array.

In some cases, at operation 325, operation 320 may be repeated a number of times. The operations may be repeated until a science array comprises a sufficient fill factor for quantum computation, quantum simulation, clock operations, metrology operations, sensing operations, etc.

The method 300 may comprise an operation 330. The operation 330 may comprise transferring at least one atom into the reservoir array to increase a fill factor of the reservoir array. The operation 330 may be performed at least partially during the transferring at least one atom from the reservoir array into the science array at operation 320.

Operation 330 may comprise an embodiment, variation, or example of operation 260 of method 200. For example, the method 300 may comprise an operation 260. Operation 260 may comprise reloading the reservoir array with additional atoms. The reservoir may be reloaded from an atom source. The atom source may be cooled atom source.

In some cases, at operation 335, operation 330 may be repeated a number of times. Operation 330 may be refilled a number of times to fill a reservoir array. The operation may be repeated such that an application, such as an application in an operation 230, may be performed continuously. The operation may be repeated such that an application, such as an application in an operation 230, may be performed substantially without stopping the application.

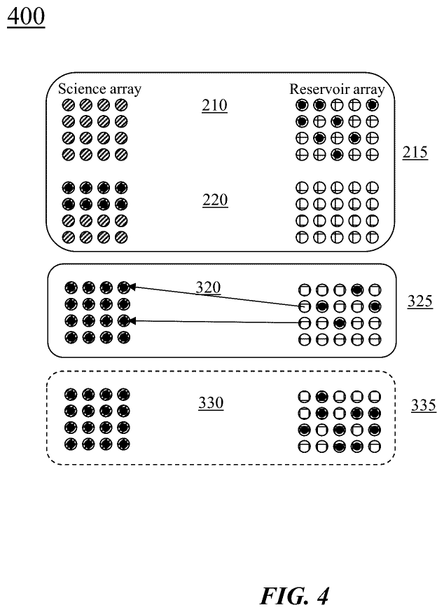

FIG. 4 shows another example method and system preparing a sample of atoms. The method 400 may an embodiment, variation, or example of an operation 210 of the method 200. Operation 210 may comprise loading a plurality of atoms into a reservoir array that includes a first plurality of spatially distinct optical trapping sites. The first plurality of optical trapping sites may be configured to trap the plurality of atoms. In some cases, the plurality of atoms are qubits in a non-classical computational system, such as a quantum computer, a quantum annealer, etc. In some cases, the plurality of atoms comprises atoms in an atomic clock.

The method 400 may comprise an embodiment, variation, or example of an operation 220 of the method 200. Operation 220 may comprise transferring a first subset of the plurality of atoms from the reservoir array into a science array. The science array may include a second plurality of spatially distinct optical trapping sites. The second plurality of optical trapping sites may be configured to trap a plurality of atoms.

In some cases, at operation 215, operations 210 and 220 may be repeated a number of times. The operations may be repeated until a science array comprises a sufficient fill factor for quantum computation, quantum simulation, clock operations, metrology operations, etc.

As shown in FIG. 4, method 400 may further comprise an embodiment, variation, or example of operations 320, 325, 330, and 335 of the method 200.

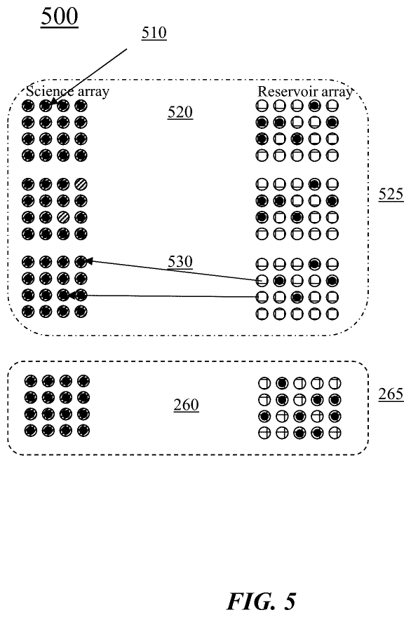

FIG. 5 shows another example method and system preparing a sample of atoms. The method 500 may comprise an operation 510. Operation 510 may comprise trapping a plurality of atoms into a science array, wherein the science array comprises a first plurality of spatially distinct optical trapping sites. The method 500 may comprise an operation 520. Operation 520 may comprise inducing at least a first subset of the plurality of atoms to adopt one or more superposition states at least a first subset of the plurality of atoms in the science array. The method 500 may comprise an operation 530. Operation 530 may comprise transferring at least one atom from a reservoir array into the science array, wherein the reservoir array comprises a second plurality of spatially distinct optical trapping sites. Operation 530 may be performed substantially without decoherence of the superposition state generated at operation 520.

In some cases, the method 500 may comprise an operation 230. Operation 230 may comprise performing a first application using at least some of the first subset of the plurality of atoms in the science array. The application may be quantum computation, quantum simulation, clock operations, metrology operations, etc. Operation 230 may itself comprise one or more instances of operation 520. For example, a two-qubit gate may comprise one or more instances of generating a superposition at operation 520.

In some cases, the method 500 may comprise determining an atomic loss in one or more of the arrays. The operation may comprise determining an atomic loss number representing a difference between (i) a number of atoms in the first subset of the plurality of atoms and (ii) a number of atoms in a remaining subset of the first subset of the plurality of atoms that remain in the science array following the performing of the first non-classical computation. Atom loss may occur due to collisions with residual background gas, to leakage into un-trapped or otherwise undesirable internal states, due to heating associated with laser interactions, or other processes.

Operation 530 may comprise an embodiment, variation, or example of operation 250 of method 200. For example, the method 500 may comprise an operation 250. Operation 250 may comprise transferring a second subset of the plurality of atoms from the reservoir array into the science array. Operation 250 may comprise a reloading operation. In some cases, the second subset of the plurality of atoms includes at least a number of atoms equal to the atomic loss number. In some cases, the second subset of the plurality of atoms includes a number of atoms less than the atomic loss number. The second subset may be transferred substantially without loss of a coherence of the plurality of atoms in the science array. The second subset may be transferred substantially without stopping an application in the science array.

In some cases, at operation 525, operations 520 and 530 may be repeated a number of times. The operations may be repeated until a quantum computation, quantum simulation, clock operation, metrology operation, etc. is complete. The operations may be repeated while there are atoms in a reservoir to be filed into the science array.

The method 500 may comprise an embodiment variation or example of an operation 260 of the method 200. For example, operation 260 may comprise reloading the reservoir array with additional atoms. The reservoir may be reloaded from an atom source. The atom source may be cooled atom source. In some cases, at operation 265, operation 260 may be repeated a number of times. Operation 260 may be refilled a number of times to fill a reservoir array. The operation may be repeated such that an application in operation 230 may be performed continuously.

### Continuous Loading

A useful error-corrected quantum computer should remove entropy faster than it can enter. One source of entropy in a trapped atom quantum computer may be atom loss.

Accordingly, it may be useful to conditionally refill sites in a trapped atom quantum computer continuously with the calculation. Continuous operation during a non-classical computation may comprise refilling a lost atom during operations of computation. For example, continuation operation in a gate-model quantum computer may comprise refilling lost atoms “mid-circuit” or between gate operations in a quantum computation. Continuous operation in a quantum simulator may comprise refilling an atom during the simulation. Continuous operation in a clock operation may comprise refilling an atom during operation of the clock. In general, continuous operation may comprise refilling an atom during the time in which the application is being implemented.

Continuous operation may comprise refilling an atom substantially without stopping the application. Substantially without stopping may comprise not performing recovery operations, such as repeating previous steps, to account for the atom loss. Such recovery operations may comprise repeating a calculation or a portion of a calculation to replace a “lost” portion.

Similarly, since each of quantum computation, quantum simulation, clock operations, metrology, and quantum sensing may utilize phenomena such as quantum coherence, it may be useful to maintain coherence while refilling atoms in an atom-based implementation of these applications (e.g., an atomic clock, a neutral atom quantum computer, etc.). For example, atoms may be refilled substantially without loss of coherence of atoms in the array. Substantially without loss of coherence may comprise contrast loss on the order of 10% or better on seconds time scale. E.g., less than 10% loss of contrast over 2 seconds, approximately 5% contrast loss over two seconds or better. Substantially without loss of coherence may comprise a contrast of better than 0.8 (maximum of 1) over 1 second.

The present disclosure provides systems and methods for continuous atom reloading. Systems and methods of the present disclosure may distinguish the science array and the reservoir array during atom transfer.

For example, the arrays may be physically distinguished. Systems and methods of the present disclosure may employ distinct sets or subsets of atoms within an array. For example, each of FIGS. 2-5 show a science array and a reservoir array. In some cases, the science array is distinct from the reservoir array. In some cases, the science array is spatially distinct from the reservoir array. For example, the science array may be physically separated from the reservoir array. For example, the science array may be energetically separated from the reservoir array during atom movement. In some cases, both physical and energetic separation methods may be used to facilitate atom movement without disruption of the science array.

Physical separation of the science array and the reservoir array may be useful in at least some respects for example. If the science array and the reservoir array are physically distinct, the reservoir array can be more easily spatially separated from the science region. This can allow loading into the reservoir array without disturbing atoms in the science region while the reservoir region is being loaded. For example, a disturbance may occur from unwanted scattering, unwanted light shifts, etc. during transfer. In some cases, a separate optical system from the trap excitation may be used to move atoms from a first array to a second array disclosed herein. For example, the reservoir array may be loaded from a separate optical potential or array, which may disturb atoms in the science region if the reservoir and science arrays were too close. Using separate optical systems to generate the two arrays may be helpful for separating the science array and the reservoir array arrays. Using a separate (e.g., a third) optical system, for atom movement may further insulate the arrays.

In some examples, the reservoir and science regions may be separated either parallel or transverse to the axis along which imaging is performed. If the separation is parallel to the imaging axis, atoms may be transferred from reservoir to science region by means of translating the focus of focused trapping lasers, or by shifting the phase of a trapping optical lattice. See for example, the section “Long Range Transport” herein. In some cases, the transfer of the at least one atom that is from the reservoir array into the science array is a long-range transfer.

Electronic separation of the science array and the reservoir array may be useful in at least some respects for example. In some examples, the reservoir and science regions are distinguished by the internal or motional state occupied by the atoms (perhaps instead of being spatially separated). In some examples, the traps may be formed with spatially or temporally incoherent or coherent light, or by non-optical electromagnetic fields.

In some cases, coherence may be protected by applying a “hiding” excitations during or partially during atom reloading into the science array. A hiding excitation may comprise placing an atom being transferred or an atom already in an array into a dark state, a clock state, or another state forbidden by selection rules from an optical excitation used for the transferring. In some examples, hiding excitations may be applied to atoms in the science array during imaging or excitation of atoms to be moved into the science portion of the array. In some cases, the at least one atom that is transferred from the reservoir array into the science array is in a dark state. In some cases, an atom that is transferred from the reservoir array into the science array is in a dark state, a clock state, or another state forbidden by selection rules from an optical excitation used for the transferring. See for example, the section “State Selected Atom Movement” herein.

### Optical Trapping

Optical Traps—Systems and methods of the present disclosure provide a plurality of spatially distinct optical traps. The plurality of optical traps may comprise an example of a plurality of optical trapping sites. For example, the plurality of optical traps may comprise any example of a plurality of optical trapping sites described herein with respect to FIGS. 2-5.

The system may comprise one or more trapping systems. The trapping systems may comprise one or more optical trapping systems. The optical trapping systems may comprise any optical trapping unit described herein. In some examples, the optical traps may be formed by tightly focused light (tweezers) or by standing-wave lattices, or by imaged masks or gratings. Optical trapping may additionally include various methods where atoms are cooled with optical illumination, e.g., a laser, and a spatially varying magnetic field to create a trap. Such optical traps may be called magneto-optical traps (MOTs).

In some cases, the plurality of spatially distinct optical traps comprises a 1D, 2D, or 3D optical trap. In some examples, the arrays may be linear, two-dimensional, three-dimensional, or may involve synthetic dimensions. A synthetic dimension may include, for example, dimensions consisting of internal atomic states or motional states. The plurality of spatially distinct optical traps may comprise single or multiple reservoir regions. In some examples, the arrays may be of regular or irregular or quasi-regular geometry.

Optical tweezers—In some cases, the plurality of spatially distinct optical traps comprises optical tweezers. The optical trapping sites may comprise one or more optical tweezers. Optical tweezers may comprise one or more focused laser beams to provide an attractive or repulsive force to hold or move the one or more atoms. The beam waist of the focused laser beams may comprise a strong electric field gradient. The atoms may be attracted or repelled along the electric field gradient to the center of the laser beam, which may contain the strongest electric field. The optical trapping sites may comprise one or more optical tweezer sites of one or more optical arrays of tweezers. The optical trapping sites may comprise one or more optical tweezer sites of one or more one-dimensional (1D) optical arrays of tweezers, two-dimensional (2D) optical arrays of tweezers, or three-dimensional (3D) optical arrays of tweezers. In some cases, the methods and systems described herein may be applied similarly to optical lattices. Optical tweezers may be useful in moving atoms or arrays of atoms.

Plurality of Trapping Arrays—Systems and methods of the present disclosure may employ distinct sets or subsets of atoms within an array. For example, each of FIGS. 2-5 show a science array and a reservoir array. In some cases, the science array is distinct from the reservoir array. In some cases, the science array is spatially distinct from the reservoir array. For example, the science array may be physically separated from the science array. In some cases, both the science array and the reservoir array are two-dimensional. In some cases, both the science array and the reservoir array are three-dimensional. In some cases, the science array has a different number of dimensions than the reservoir array.

In some cases, both the science array and the reservoir array are formed using a MOT. In some cases, both the science array and the reservoir array are formed using optical tweezers. In some cases, either or both of the science array or the reservoir array are formed using either light or non-optical electromagnetic fields. In some cases, the science array and the reservoir array comprise spatially distinct MOTs. In some cases, the science array comprises a first MOT in a first chamber, and the reservoir array comprises a second MOT in a second chamber. In some cases, the science array and the reservoir array comprise different regions within the same MOT.

While each of FIGS. 2-5 show a science array and a reservoir array, systems and methods of the present disclosure may comprise one or more additional arrays, e.g., intermediate arrays. For example, improved cooling may be accomplished with multi-stage MOTs. For example, a first MOT may cool to a first temperature and a second MOT may cool to a second temperature. In some cases, a multi-stage MOT may aid in spatial separation of the arrays. For example, a first MOT generated by a first optical illumination and physically separated from a second MOT may be more insulated from heat, atom loss, thermal noise, etc. from the second MOT than would different regions of the same MOT.

In some cases, in any of the methods disclosed herein, transferring at least one atom from a reservoir array into a science array comprises: transferring a first number of atoms from the reservoir array to one or more intermediate arrays and transferring a second number of atoms from the one or more intermediate arrays to the science array. In some cases, the one or more intermediate arrays includes at least two intermediate arrays. In some cases, at least some number of atoms are transferred between the at least two intermediate arrays (i) after some number of atoms are transferred to the at least two intermediate arrays from the reservoir array and (ii) before the number of atoms are transferred from the at least two intermediate arrays to the science array.

Sites—The optical trapping system may be configured to generate a plurality of optical trapping sites. The optical trapping system may be configured to generate a plurality of spatially distinct optical trapping sites. As shown in each of FIGS. 2-5, each array may comprise a plurality of spatially distinct optical trapping sites. While each optical trapping site is shown with only a single atom, in some cases, it may be advantageous to have more than one atom in a single site. In some cases, it may be preferable to have a single atom in a single site. For example, a single atom in a single site may be easier to cool because of a reduced number of collisions with other atoms.

In some cases, a second number of sites in the second plurality of optical trapping sites is equal to a first number of sites in the first plurality of optical trapping sites. In some cases, a second number of sites in the second plurality of optical trapping sites is greater than a first number of sites in the first plurality of optical trapping sites. For example, the number traps in the science array may be the same as the number of traps in the reservoir array. However, in some cases, it may be more useful to have a greater or lesser number of traps in the reservoir array.

In some cases, each of the science array, the reservoir array, and any intermediate arrays may be generated by the same or different optical trapping systems. For example, each optical trapping system may be varied based on the needs of the particular array (science, reservoir, intermediate, etc.). Each optical trapping system may comprise any number of sites disclosed herein. Each optical trapping system may comprise any number of trapped atoms disclosed herein.

For instance, each optical trapping system may be configured to generate at least about 10, 20, 30, 40, 50, 60, 70, 80, 90, 100, 200, 300, 400, 500, 600, 700, 800, 900, 1,000, 2,000, 3,000, 4,000, 5,000, 6,000, 7.000, 8,000, 9,000, 10,000, 20,000, 30,000, 40,000, 50.000, 60.000, 70,000, 80,000, 90,000, 100,000, 200,000, 300,000, 400,000, 500,000, 600,000, 700,000, 800,000, 900,000, 1,000,000, or more optical trapping sites. Each optical trapping system may be configured to generate at most about 1,000,000, 900,000, 800,000, 700,000, 600,000, 500,000, 400,000, 300,000, 200,000, 100.000, 90.000, 80,000, 70,000, 60,000, 50,000, 40,000, 30,000, 20,000, 10,000, 9,000, 8,000, 7,000, 6,000, 5,000, 4.000, 3,000, 2,000, 1,000, 900, 800, 700, 600, 500, 400, 300, 200, 100, 90, 80, 70, 60, 50, 40, 30, 20, 10, or fewer optical trapping sites. The optical trapping system(s) may be configured to trap a number of optical trapping sites that is within a range defined by any two of the preceding values.

Each optical trapping system may be configured to trap a plurality of atoms. For instance, each optical trapping system may be configured to trap a total number of atoms in the plurality of optical trapping sites of at least about 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70.000, 80.000, 90,000, 100,000, 200,000, 300,000, 400,000, 500,000, 600,000, 700,000, 800,000, 900,000, 1,000,000, or more atoms. For example, the optical trapping system(s) may be configured to trap a total number of atoms in the plurality of optical trapping sites of at most about 1,000,000, 900,000, 800,000, 700.000, 600,000, 500,000, 400,000, 300,000, 200.000, 100.000, 90.000, 80,000, 70,000, 60,000, 50,000, 40,000, 30,000, 20,000, 10.000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, or fewer atoms. The optical trapping system(s) may be configured to trap a number of atoms that is within a range defined by any two of the preceding values.

Trap Excitation—In some cases, method and systems disclosed herein may be configured to form a plurality of optical trapping sites using a trap excitation. The trap excitation may comprise an optical excitation, such as in a magneto-optical trap, an optical tweezer, etc. In some cases, the trap excitation is delivered by one or more optical trapping systems as disclosed herein. In some cases, each optical trapping system comprises its own trap excitation (e.g., trap wavelength, trap power, trap focus, number of spots, etc.). In some cases, a single trap excitation may be split into multiple arrays in order to form a plurality of arrays of traps with similar characteristics.

In some examples, using separate lasers or optics (e.g., “optical excitations”) to form the reservoir array (as compared to the lasers or optics that may be used with the science array, for example) may be useful for one or more reasons. In one example, different laser wavelengths, trap geometries (e.g., tweezer-spot sizes or spacings), or methods for generating the different arrays (e.g., acousto-optic deflectors (AODs), spatial light modulators (SLMs), digital mirror devices (DMDs), micro-lens arrays, diffraction gratings, standing wave lattices, imaged structures, or other) can be used to create the reservoir and science arrays. Therefore, the properties (trap depths, differential polarizabilities on relevant atomic transitions, trap spacing, trap oscillation frequency, etc.) of each array can be optimized for its specific role. In another example, power from a single source is typically limited and by using multiple sources, the total available power can be increased, allowing more and/or deeper traps to be formed.

The optical trapping system(s) may comprise one or more light sources configured to emit light to generate the plurality of optical trapping sites as described herein. For instance, the optical trapping system(s) may comprise a single light source. In some cases, the optical trapping system(s) may comprise any number of light sources, such as at least about 1, 2, 3, 4, 5, 6, 7, 8, 9, 10, or more light sources or at most about 10, 9, 8, 7, 6, 5, 4, 3, 2, or 1 light sources. The light sources may comprise one or more lasers.

The light sources may be configured to direct light to one or more optical modulators (OMs) configured to generate the plurality of optical trapping sites. For instance, the optical trapping unit may comprise an OM configured to generate the plurality of optical trapping sites. In some cases, the optical trapping unit may comprise any number of OMs, such as at least about 1, 2, 3, 4, 5, 6, 7, 8, 9, 10, or more OMs or at most about 10, 9, 8, 7, 6, 5, 4, 3, 2, or 1 OMs. The OMs may comprise one or more digital micromirror devices (DMDs). The OMs may comprise one or more liquid crystal devices, such as one or more liquid crystal on silicon (LCoS) devices. The OMs may comprise one or more spatial light modulators (SLMs). The OMs may comprise one or more acousto-optic deflectors (AODs) or acousto-optic modulators (AOMs). The OMs may comprise one or more electro-optic deflectors (EODs) or electro-optic modulators (EOMs).

The OM may be optically coupled to one or more optical element to generate a regular array of optical trapping sites. The optical elements may comprise lenses or microscope objectives configured to re-direct light from the OMs to form a regular rectangular grid of optical trapping sites.

For instance, the OM may comprise an SLM, DMD, or LCoS device. The SLM, DMD, or LCoS device may be imaged onto the back focal plane of the microscope objectives. This may allow for the generation of an arbitrary configuration of optical trapping sites in two or three dimensions.

In some cases, the trap excitation may be turned on or off during the course of the methods, operations, and applications disclosed herein. For example, a trap light may be on during a loading phase of the array of optical traps. For example, a trap light may be off during or after a phase when a second optical excitation is applied. e.g., an optical excitation for an application of the present disclosure, such as a non-classical computing operation, a clock operation, a metrology operation, a sensing operation, etc. For example, a trap with an initial number of atoms in a science array may be provided. A Rydberg excitation may be applied to form an optical coherence between two atoms in the science array. One or atoms may be added to the science array. During the optical excitation to form the coherence, the trap light may be temporarily turned off.

In some cases, the trap excitation for each optical trapping system comprises 399 nm ¹P₁ transition followed by the 556 nm ³P₁ narrow-line transition. The trap excitation for each optical trapping system may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

### Atoms

Systems and methods of the present disclosure may be applied to any atomic system that may be cooled and trapped. In some cases, the plurality of atoms comprises neutral atoms. In some cases, the plurality of atoms comprises a Group II element. In some cases, the plurality of atoms comprises Scandium. In some cases, the plurality of atoms comprises a Group II-like element. In some cases, the plurality of atoms an atom with two-valence electrons. In some cases, the plurality of atoms comprises Ytterbium.

Atoms—The optical trapping system may be configured to trap neutral atoms. In some cases, the optical trapping system may trap alkaline earth or an alkaline earth-like atom. In some cases, an alkaline earth-like atom comprises two valence electrons. In some cases, an alkaline earth or an alkaline earth-like atom comprises strontium or ytterbium.

One or more atoms may comprise alkali atoms. One or more atoms may comprise lithium (Li) atoms, sodium (Na) atoms, potassium (K) atoms, rubidium (Rb) atoms, or cesium (Cs) atoms. One or more atoms may comprise lithium-6 atoms, lithium-7 atoms, sodium-23 atoms, potassium-39 atoms, potassium-40 atoms, potassium-41 atoms, rubidium-85 atoms, rubidium-87 atoms, or caesium-133 atoms. One or more atoms may comprise alkaline earth atoms. One or more atoms may comprise beryllium (Be) atoms, magnesium (Mg) atoms, calcium (Ca) atoms, strontium (Sr) atoms, or barium (Ba) atoms. One or more atoms may comprise beryllium-9 atoms, magnesium-24 atoms, magnesium-25 atoms, magnesium-26 atoms, calcium-40 atoms, calcium-42 atoms, calcium-43 atoms, calcium-44 atoms, calcium-46 atoms, calcium-48 atoms, strontium-84 atoms, strontium-86 atoms, strontium-87 atoms, strontium-88 atoms, barium-130 atoms, barium-132 atoms, barium-133, barium-134 atoms, barium-135 atoms, barium-136 atoms, barium-137 atoms, or barium-138 atoms. One or more atoms may comprise rare earth atoms. One or more atoms may comprise scandium (Sc) atoms, yttrium (Y) atoms, lanthanum (La) atoms, cerium (Ce) atoms, praseodymium (Pr) atoms, neodymium (Nd) atoms, samarium (Sm) atoms, europium (Eu) atoms, gadolinium (Gd) atoms, terbium (Tb) atoms, dysprosium (Dy) atoms, holmium (Ho) atoms, erbium (Er) atoms, thulium (Tm) atoms, ytterbium (Yb) atoms, or lutetium (Lu) atoms. One or more atoms may comprise scandium-45 atoms, yttrium-89 atoms, lanthanum-139 atoms, cerium-136 atoms, cerium-138 atoms, cerium-140 atoms, cerium-142 atoms, praseodymium-141 atoms, neodymium-142 atoms, neodymium-143 atoms, neodymium-145 atoms, neodymium-146 atoms, neodymium-148 atoms, samarium-144 atoms, samarium-149 atoms, samarium-150 atoms, samarium-152 atoms, samarium-154 atoms, europium-151 atoms, europium-153 atoms, gadolinium-154 atoms, gadolinium-155 atoms, gadolinium-156 atoms, gadolinium-157 atoms, gadolinium-158 atoms, gadolinium-160 atoms, terbium-159 atoms, dysprosium-156 atoms, dysprosium-158 atoms, dysprosium-160 atoms, dysprosium-161 atoms, dysprosium-162 atoms, dysprosium-163 atoms, dysprosium-164 atoms, erbium-162 atoms, erbium-164 atoms, erbium-166 atoms, erbium-167 atoms, erbium-168 atoms, erbium-170 atoms, holmium-165 atoms, thulium-169 atoms, ytterbium-168 atoms, ytterbium-170 atoms, ytterbium-171 atoms, ytterbium-172 atoms, ytterbium-173 atoms, ytterbium-174 atoms, ytterbium-176 atoms, lutetium-175 atoms, or lutetium-176 atoms.

### Atom Movement Units

As disclosed here, the systems and methods disclosed herein may use a plurality of arrays of optical traps (e.g., a science array, a reservoir array, an intermediate array, etc.). In some cases, the science array is distinct from the reservoir array. In some cases, the science array is spatially distinct from the reservoir array. For example, the science array may be physically separated from the science array.

Physical separation of the science array and the reservoir array may be useful in at least some respects. For example, if the science array and the reservoir array are physically distinct, the reservoir array can be more easily spatially separated from the science region. This can allow loading into the reservoir array without disturbing atoms in the science region w % bile the reservoir region is being loaded. For example, a disturbance may occur from unwanted scattering, unwanted light shifts, etc. during transfer. In some cases, a separate optical system from the trap excitation may be used to move atoms from a first array to a second array disclosed herein. For example, the reservoir array may be loaded from a separate optical potential or array, which may disturb atoms in the science region if the reservoir and science arrays were too close. Using separate optical systems to generate the two arrays may be helpful for separating the science array and the reservoir array arrays. Using a separate (e.g., a third) optical system, for atom movement may further insulate the arrays.

Moving atoms between arrays and rearranging atoms within an array may be accomplished by the atom movement units disclosed herein. An atom movement unit may comprise any embodiment, variation, or example of an atom rearrangement unit disclosed herein. For example, operations 220, 250, 320, and 530 as described herein may comprise moving atoms from the reservoir array to the science array.

In some examples, present techniques may be combined with methods for probabilistic, deterministic or near-deterministic loading of optical or other traps, such as those disclosed herein. In some examples, atoms within the science region may or may not be rearranged as the science array is replenished. In some examples, atoms can be transferred between the reservoir and science regions by optical tweezers. In some examples, atoms can be transferred between the reservoir and science regions by optical lattices. In some examples, atoms can be transferred between the reservoir and science regions by tunneling/hopping between sites. In some examples, atoms can be transferred between the reservoir and science regions by autonomous stabilization techniques. Autonomous stabilization techniques may comprise imaging of the initial and/or final occupancies of the science and/or reservoir regions and autonomously updating the occupancies of sites of the array.

In some cases, one or both of (i) loading the plurality of atoms into the reservoir or (ii) reloading the reservoir array with the additional atoms, is performed using one or both of a moving optical trap or an optical tweezer. In some cases, an optical tweezer may be used to move a single atom (e.g., pick and place) or a subset of atoms between arrays or within an array. In some cases, a moving optical trap can be used to translate or compress an array. A moving optical trap may implement a tone to sweep atoms from one location to another. The atom movement units may be configured to move the one or more replacement atoms from the one or more atoms reservoirs to the one or more optical trapping sites. For instance, the one or more atom movement units may comprise one or more electrically tunable lenses, acousto-optic deflectors (AODs), or spatial light modulators (SLMs).

In some cases, the science array is physically separated from the reservoir array parallel to the imaging axis; and one or both of (i) transferring the first subset of the plurality of atoms from the reservoir array into the science array or (ii) transferring the second subset of the plurality of atoms from the reservoir array into the science array, is performed using one or both of a moving optical trap or an optical tweezer.

In some cases, any of the methods 200, 300, 400, or 500 may comprise rearranging, within the science array, positions among the plurality of spatially distinct optical trapping sites of at least some of one or both of (i) the plurality of atoms in the science array or (ii) the at least one atom in a science array. In some cases, any of the methods 200, 300, 400, or 500 may comprise rearranging, within the reservoir array, positions among the plurality of spatially distinct optical trapping sites of at least some of one or both of (i) the plurality of atoms in the reservoir array or (ii) the at least one atom in the reservoir array.

The optical trapping system(s) disclosed herein may comprise one or more atom rearrangement units configured to impart an altered spatial arrangement of the plurality of atoms trapped with the optical trapping sites based on the one or more images obtained by the imaging unit. The optical trapping unit may comprise any number of atom rearrangement units, such as at least about 1, 2, 3, 4, 5, 6, 7, 8, 9, 10, or more atom rearrangement units or at most about 10, 9, 8, 7, 6, 5, 4, 3, 2, or 1 atom rearrangement units. In some cases, the science array is associated with a first spatial light modulator and the reservoir array is associated with a second spatial light modulator.

The atom rearrangement unit may be configured to alter the spatial arrangement in order to obtain an increase in a filling factor of the plurality of optical trapping sites. A filling factor may be defined as a ratio of the number of computationally active optical trapping sites occupied by one or more atoms to the total number of computationally active optical trapping sites available in the optical trapping unit or in a portion of the optical trapping unit. For instance, initial loading of atoms within the computationally active optical trapping sites may give rise to a filling factor of less than 100%, 90%, 80%, 70%, 60%, 50%, or less, such that atoms occupy fewer than 100%, 90%, 70%, 60%, 50%, or less of the available computationally active optical trapping sites, respectively. It may be desirable to rearrange the atoms to achieve a filling factor of at least about 50%, 60%, 70%, 80%, 90%, or 100%. By analyzing the imaging information obtained by the imaging unit, the atom rearrangement unit may attain a filling factor of at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, 99.9%, 99.91%, 99.92%, 99.93%, 99.94%, 99.95%, 99.96%, 99.97%, 99.98%, 99.99%, or more. The atom rearrangement unit may attain a filling factor of at most about 99.99%, 99.98%, 99.97%, 99.96%, 99.95%, 99.94%, 99.93%, 99.92%, 99.91%, 99.9%, 99.8%, 99.7%, 99.6%, 99.5%, 99.4%, 99.3%, 99.2%, 99.1%, 99%, 98%, 97%, 96%, 95%, 94%, 93%, 92%, 91%, 90%, 80%, 70%, 60%, 50%, or less. The atom rearrangement unit may attain a filling factor that is within a range defined by any two of the preceding values.

In some cases, atom rearrangement may be performed by (i) acquiring an image of the optical trapping unit, identifying filled and unfilled optical trapping sites, (ii) determining a set of moves to bring atoms from filled optical trapping sites to unfilled optical trapping sites, and (iii) moving the atoms from filled optical trapping sites to unfilled optical trapping sites. Operations (i), (ii), and (iii) may be performed iteratively until a large filling factor is achieved. Operation (iii) may comprise translating the moves identified in operation (ii) to waveforms that may be sent to an arbitrary waveform generator (AWG) and using the AWG to drive AODs to move the atoms.

### Lone Range Transfer

As spatial separation of the science array and the reservoir array increases interaction between the two arrays may decrease; however, it may become more difficult to move atoms between arrays. Systems and methods of the present disclosure may integrate long range transfer techniques in order to facilitate greater physical separation.

In an example long range transfer technique, an optical lattice may be created by interfering two opposing laser beams whose focal points overlap with one another. Atoms may be transported by translating the phase of the optical lattice while simultaneously translating the foci of the two opposing laser beams, such that the two foci remain overlapped and also track the phase of the lattice during the entire journey of the atoms. The tight confinement of the optical lattice enables fast transport due to the large restoring force caused by the high intensity gradient created by the lattice. The translating laser foci allow for the trap depth to be maximized with minimum laser power throughout the entire trajectory.

In order to achieve a deep lattice in a power-efficient manner, the waists of the transport beams may be translated synchronously with the optical lattice by moving the position of two focusing lenses, one for each of the two counterpropagating beams that form the lattice. Alignment between the two beams may be actively maintained using closed-loop piezo-electric steering mirrors. Atoms are transferred into the optical tweezer array by overlapping the atoms with the array, ramping up the power in the tweezers, and then ramping down the transport lattice.

In some cases, a long-range transfer method may comprise cooling and trapping the plurality of atoms within a one-dimensional optical lattice using one or more electromagnetic waves. In some cases, a long-range transfer method may comprise ceasing the cooling of the plurality of atoms within the one-dimensional optical lattice. In some cases, a long-range transfer method may comprise chirping a relative frequency and/or adjusting a focal depth of one or more lens to maintain trapping of the plurality of atoms. In some cases, a long-range transfer method may comprise changing an angle of the one or more electromagnetic waves to transport a set of atoms of the plurality of atoms within the optical lattice. In some cases, a long-range transfer method may comprise performing the computation using the plurality of atoms.

In some embodiments, chirping a relative frequency comprises translating a phase of the one-dimensional optical lattice. In some embodiments, translating a phase of the one-dimensional lattice comprises transporting one or more atoms from a first zone to a second zone. In some embodiments, the first zone is an atom loading zone (e.g., a reservoir array), and the second zone is a science array. In some embodiments, transporting one or more atoms from a first zone to a second zone comprises transporting the one or more atoms across a distance. In some embodiments, the distance is at least about 20 cm. In some embodiments, the distance ranges from about 20 cm to about 100 cm. In some embodiments, translating a phase of the one-dimensional optical lattice comprises changing an angle of a mirror. In some embodiments, adjusting a focal depth of one or more lenses comprises changing a position of the one or more lenses.

### Cooling/State Preparation

The science array and the reservoir array may be integrated with a cooling process. It may be advantageous for some applications for each atom to be in substantially the same state or a substantially determined/determinable state, such that an application (e.g., metrology, sensing, optical clocks, non-classical computation, quantum simulation, etc.) may be performed. The optical trapping systems disclosed herein (e.g., for the science array, the reservoir array) may be integrated with the state preparation systems disclosed herein.

As disclosed above, improved cooling may be accomplished with multi-stage MOTs. For example, a first MOT may cool to a first temperature and a second MOT may cool to a second temperature. In some cases, a multi-stage MOT may aid in spatial separation of the arrays. For example, a first MOT generated by a first optical illumination and physically separated from a second MOT may be more insulated from heat, atom loss, thermal noise, etc. from the second MOT than would different regions of the same MOT. In some cases, a single MOT may comprise multiple cooling operations. For example, a first cooling operation may comprise using an electromagnet delivery unit or units to deliver a 399 nm ¹P₁ transition followed by a 556 nm ³P₁ narrow-line transition.

In an example, operation 210 and 260 as disclosed herein with respect to method 200, 300, 400, and 500 may comprise initial load and/or reloading the reservoir array with additional atoms. The reservoir may be reloaded from an atom source. The atom source may be cooled atom source. In some examples, reservoir regions may be filled from a magneto-optical trap (MOT), from an atomic beam, from a thermal atomic gas, from another optical or other form of electromagnetic trap, or from any other source of atoms. In some examples, the initial loading of the science region (e.g., operation 220 herein) may be direct (from any atomic source other than the reservoir array), from the reservoir array, or from a separate reservoir array than the one used for replenishing. In some examples, the reservoir region may be smaller, larger, or the same size/number of sites as the science region and similar techniques may be used to maintain an arbitrary number of atoms within each site of the science array.

State Preparation—The systems and methods disclosed herein may comprise one or more state preparation units. A state preparation unit may comprise a portion of an atom source. A state preparation unit may be configured to prepare a state of the plurality of atoms, as described herein. The state preparation unit may be coupled to the optical trapping unit and may direct atoms that have been prepared by the state preparation unit to the optical trapping unit. The state preparation unit may be configured to cool the plurality of atoms. The state preparation unit may be configured to cool the plurality of atoms prior to trapping the plurality of atoms at the plurality of optical trapping sites.

In some cases, the state preparation unit comprises one or more atom reservoirs. The atom reservoirs may be configured to supply one or more replacement atoms to replace one or more atoms at one or more optical trapping sites upon loss of the atoms from the optical trapping sites of the science array or the reservoir array. The atom reservoirs may be spatially separated from the optical traps of the science array or the reservoir array. For instance, the atom reservoirs may be located at a distance from the optical traps of the reservoir array and the science array.

In some cases, the atom reservoirs may comprise a portion of the optical trapping sites of the optical trapping units (e.g., the reservoir array is a subset of the science array). A first subset of the optical trapping sites may be utilized for performing quantum computations and may be referred to as a set of computationally active optical trapping sites (e.g., a science array), while a second subset of the optical trapping sites may serve as an atom reservoir. For instance, the first subset of optical trapping sites may comprise an interior array of optical trapping sites, while the second subset of optical trapping sites comprises an exterior array of optical trapping sites surrounding the interior array. The interior array may comprise a rectangular, square, rectangular prism, or cubic array of optical trapping sites.

The state preparation unit may be coupled to the optical trapping unit and may direct atoms that have been prepared by the state preparation unit to the optical trapping unit. The state preparation unit may be configured to cool the plurality of atoms. The state preparation unit may be configured to cool the plurality of atoms prior to trapping the plurality of atoms at the plurality of optical trapping sites.

The state preparation unit may comprise one or more Zeeman slowers. For instance, the state preparation unit may comprise a Zeeman slower. The state preparation may comprise any number of Zeeman slowers, such as at least about 1, 2, 3, 4, 5, 6, 7, 8, 9, 10, or more Zeeman slowers or at most about 10, 9, 8, 7, 6, 5, 4, 3, 2, or 1 Zeeman slowers. The Zeeman slowers may be configured to cool one or more atoms of the plurality of atoms from a first velocity or distribution of velocities (such an emission velocity from an of an atom source, room temperature, liquid nitrogen temperature, or any other temperature) to a second velocity that is lower than the first velocity or distribution of velocities.

The first velocity or distribution of velocities may be associated with a temperature of at least about 50 Kelvin (K), 60 K, 70 K, 80 K, 90 K, 100 K, 200 K, 300 K, 400 K, 500 K, 600 K, 700 K, 800 K, 900 K, 1,000 K, or more. The first velocity or distribution of velocities may be associated with a temperature of at most about 1,000 K, 900 K, 800 K, 700 K, 600 K, 500 K, 400 K, 300 K, 200 K, 100 K, 90 K, 80 K, 70 K, 60 K, 50 K, or less. The first velocity or distribution of velocities may be associated with a temperature that is within a range defined by any two of the preceding values. The second velocity may be at least about 1 meter per second (m/s), 2 m/s, 3 m/s, 4 m/s, 5 m/s, 6 m/s, 7 m/s, 8 m/s, 9 m/s, 10 m/s, or more. The second velocity may be at most about 10 m/s, 9 m/s, 8 m/s, 7 m/s, 6 m/s, 5 m/s, 4 m/s, 3 m/s, 2 m/s, 1 m/s, or less. The second velocity may be within a range defined by any two of the preceding values. The Zeeman slowers may comprise 1D Zeeman slowers.

The state preparation unit may comprise one or more magneto-optical traps (MOT). The one or more MOTs may be configured to cool the atoms to a first temperature. The temperature may be at most about 10 millikelvin (mK), 9 mK, 8 mK, 7 mK, 6 mK, 5 mK, 4 mK, 3 mK, 2 mK, 1 mK, 0.9 mK, 0.8 mK, 0.7 mK, 0.6 mK, 0.5 mK, 0.4 mK, 0.3 mK, 0.2 mK, 0.1 mK, or less. The first temperature may be at least about 0.1 mK, 0.2 mK, 0.3 mK, 0.4 mK, 0.5 mK, 0.6 mK, 0.7 mK, 0.8 mK, 0.9 mK, 1 mK, 2 mK, 3 mK, 4 mK, 5 mK, 6 mK, 7 mK, 8 mK, 9 mK, 10 mK, or more. The first temperature may be within a range defined by any two of the preceding values. The MOT may comprise a 1D, 2D, or 3D MOT.

The state preparation unit may comprise one or more sideband cooling units or Sisyphus cooling units (such as a sideband cooling unit described in www.arxiv.org/abs/1810.06626 or a Sisyphus cooling unit described in www.arxiv.org/abs/1811.06014, each of which is incorporated herein by reference in its entirety for all purposes). The state preparation may comprise any number of sideband cooling units or Sisyphus cooling units, such as at least about 1, 2, 3, 4, 5, 6, 7, 8, 9, 10, or more sideband cooling units or Sisyphus cooling units, or at most about 10, 9, 8, 7, 6, 5, 4, 3, 2, or 1 sideband cooling units or Sisyphus cooling units. The sideband cooling units or Sisyphus cooling units may be configured to use sideband cooling to cool the atoms from the second temperature to a third temperature that is lower than the second temperature. The third temperature may be at most about 10 μK, 9 μK, 8 μK, 7 μK, 6 μK, 5 μK, 4 μK, 3 μK, 2 μK, 1 μK, 900 nK, 800 nK, 700 nK, 600 nK, 500 nK, 400 nK, 300 nK, 200 nK, 100 nK, 90 nK, 80 nK, 70 nK, 60 nK, 50 nK, 40 nK, 30 nK, 20 nK, 10 nK, or less. The third temperature may be at most about 10 nK, 20 nK, 30 nK, 40 nK, 50 nK, 60 nK, 70 nK, 80 nK, 90 nK, 100 nK, 200 nK, 300 nK, 400 nK, 500 nK, 600 nK, 700 nK, 800 nK, 900 nK, 1 μK, 2 μK, 3 μK, 4 μK, 5 μK, 6 μK, 7 μK, 8 μK, 9 μK, 10 μK, or more. The third temperature may be within a range defined by any two of the preceding values.

The sideband cooling units or Sisyphus cooling units may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The state preparation unit may comprise one or more optical pumping units. The state preparation may comprise any number of optical pumping units, such as at least about 1, 2, 3, 4, 5, 6, 7, 8, 9, 10, or more optical pumping units, or at most about 10, 9, 8, 7, 6, 5, 4, 3, 2, or 1 optical pumping units. The optical pumping units may be configured to emit light to optically pump the atoms from an equilibrium distribution of atomic states to a non-equilibrium atomic state. For instance, the optical pumping units may be configured to emit light to optically pump the atoms from an equilibrium distribution of atomic states to a single pure atomic state. The optical pumping units may be configured to emit light to optically pump the atoms to a ground atomic state or to any other atomic state. The optical pumping units may be configured to optically pump the atoms between any two atomic states. The optical pumping units may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The state preparation unit may comprise one or more coherent driving units. The state preparation may comprise any number of coherent driving units, such as at least about 1, 2, 3, 4, 5, 6, 7, 8, 9, 10, or more coherent driving units or at most about 10, 9, 8, 7, 6, 5, 4, 3, 2, or 1 coherent driving units. The coherent driving units may be configured to coherently drive the atoms from the non-equilibrium state to the first or second atomic states described herein. Thus, the atoms may be optically pumped to an atomic state that is convenient to access (for instance, based on availability of light sources that emit particular wavelengths or based on other factors) and then coherently driven to atomic states described herein that are useful for performing quantum computations. The coherent driving units may be configured to induce a single photon transition between the non-equilibrium state and the first or second atomic state. The coherent driving units may be configured to induce a two-photon transition between the non-equilibrium state and the first or second atomic state. The two-photon transition may be induced using light from two light sources described herein (such as two lasers described herein).

The coherent driving units may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1.000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The coherent driving units may be configured to induce an RF transition between the non-equilibrium state and the first or second atomic state. The coherent driving units may comprise one or more electromagnetic radiation sources configured to emit electromagnetic radiation configured to induce the RF transition. For instance, the coherent driving units may comprise one or more RF sources (such as any RF source described herein) configured to emit RF radiation. The RF radiation may comprise one or more wavelengths of at least about 10 centimeters (cm), 20 cm, 30 cm, 40 cm, 50 cm, 60 cm, 70 cm, 80 cm, 90 cm, 1 meter (m), 2 m, 3 m, 4 in, 5 m, 6 m, 7 m, 8 m, 9 m, 10 m, or more. The RF radiation may comprise one or more wavelengths of at most about 10 m, 9 m, 8 m, 7 m, 6 m, 5 m, 4 m, 3 m, 2 m, 1 m, 90 cm, 80 cm, 70 cm, 60 cm, 50 cm, 40 cm, 30 cm, 20 cm, 10 cm, or less. The RF radiation may comprise one or more wavelengths that are within a range defined by any two of the preceding values. Alternatively, or in addition, the coherent driving units may comprise one or more light sources (such as any light sources described herein) configured to induce a two-photon transition corresponding to the RF transition.

### Atom Loss and Imaging

In some cases, any of the methods disclosed herein (e.g., 200, 300, 400, 500) may further comprise determining an atomic loss number representing a difference between (i) a number of atoms in the plurality of atoms trapped into the science array and (ii) a number of atoms in a remaining subset of the plurality of atoms trapped into the science array that remain in the science array following the performing of at least some of the non-classical computation.

An atom loss may be determined by imaging one or more atoms in any array. Imaging may be affected by exciting an atom into a state that emits, for example, a fluorescing state, a state that spontaneously emits, a state undergoes stimulated emission, a phosphorescing state. Scattered photons after imaging may be collected on a camera or a detector.

In some cases, atoms may be moved into the science array to fill atoms observed to be lost. For example, the at least one atom transferred from the reservoir array into the science array comprise a number of atoms equal to at least the atomic loss number. In some cases, determining an atomic loss number is based on imaging across an imaging axis to determine which sites of the second plurality of spatially distinct optical trapping sites of the science array are occupied.

In some examples, atoms can be transferred between the reservoir and science regions by autonomous stabilization techniques. Autonomous stabilization techniques may comprise imaging of the initial and/or final occupancies of the science and/or reservoir regions and autonomously updating the occupancies of sites of the array. In this method, a fill factor of the array may be actively maintained.

### State Selected Atom Movement

In some cases, coherence may be protected by applying a “hiding” excitations during or partially during atom reloading into the science array. A hiding excitation may comprise placing an atom being transferred or an atom already in an array into a dark state, a clock state, or another state forbidden by selection rules from an optical excitation used for the transferring. In some examples, hiding excitations may be applied to atoms in the science array during imaging or excitation of atoms to be moved into the science portion of the array.

In some cases, an atom that is transferred from the reservoir array into the science array is in a dark state, a clock state, or another state forbidden by selection rules from an optical excitation used for the transferring. In some cases, an additional optical tweezer array (separate from a tweezer used for trapping or movement) may be generated which may address a subset of atoms with a hiding light. For example, an optical tweezer that addresses a subset of sites, at a wavelength with large differential polarizability between the qubit and imaging transition may hide selected qubits from the imaging light. For example, a hiding wavelength may be relatively near-detuned (˜2 nm) from the imaging transition to another higher transition leading to a larger light shift of the imaging state than the qubit states, thereby pushing the imaging light off resonance. In other examples, the hiding transition may be putting an atom in a metastable state, a different spin state that is protected via polarization (e.g., shelving via a spin state with different angular momentum state).

### Applications

In some examples, the atoms in the science array may be used for metrology, communications, information storage, computation, simulation, or any other application. In some examples, the present techniques (e.g., the process 200, 300, 400, 500, or 600) may be applied to quantum computers or simulations devices using one or multiple species of atoms or molecules.

In some cases, the methods and system disclosed herein may comprise performing a sensing application using the at least the first subset of the plurality of atoms. For example, the plurality of atoms disclosed herein may be used for force sensing. For example, the plurality of atoms disclosed herein may be used for distance sensing. A distance sensing application may comprise using the plurality of atoms for interferometry.

In some cases, the methods and system disclosed herein may comprise performing a time-keeping operation using the at least the first subset of the plurality of atoms. For example, one use of trapped atom arrays is in atomic clocks. In some cases, the methods and system disclosed herein may comprise performing a metrology operation using the at least the first subset of the plurality of atoms.

In some cases, the methods and system disclosed herein may comprise performing a computation using the at least the first subset of the plurality of atoms. For example, the computation may be a non-classical computation, and the computation may be performed substantially without stopping the non-classical computation. In some cases, the non-classical computation may comprise applying electromagnetic energy to one or more atoms of the first subset of the plurality of atoms in the science array, thereby inducing the one or more atoms to adopt one or more superposition states of a first atomic state and at least a second atomic state that is different from the first atomic state. As disclosed herein, the refilling operations may be performed substantially without loss of the one or more superposition states. In some cases, the non-classical computation may comprise quantum mechanically entangling at least one of the one or more atoms in the one or more superposition states with at least another atom of the first subset of the plurality of atoms in the science array. As disclosed herein, the refilling operations may be performed substantially without loss of the entanglement. In some cases, the non-classical computation may comprise one or more measurement operations. For example, a method may comprise measuring one or more superposition states to obtain a non-classical result.

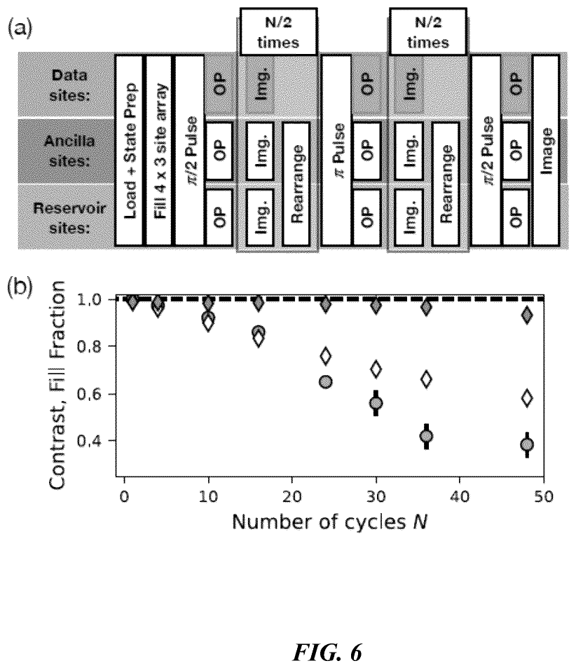

In some cases, the application is a non-classical computation, and the plurality of atoms are qubits. For example, the qubits may comprise nuclear spin qubits. A method or system comprising a nuclear spin qubit may comprise one or more superposition states of a first atomic state and a second atomic state where the first and second atomic states comprise first nuclear spin states and second nuclear spin states of a nucleus comprising a nuclear spin greater than or equal to %. In some cases, the one or more atoms of the first subset of the plurality of atoms in the one or more superposition states and the at least another atom of the first subset of the plurality of atoms in the science array are quantum mechanically entangled with a coherence lifetime of at least 1 second. In some cases, the qubit state displays coherence characteristics as shown in FIG. 6.

Electromagnetic delivery units—The electromagnetic delivery unit may be configured to apply electromagnetic energy to one or more atoms of the plurality of atoms, as described herein. The electromagnetic delivery unit may comprise one or more light sources, such as any light source described herein. The electromagnetic energy may comprise optical energy. The optical energy may comprise any repetition rate, pulse energy, average power, wavelength, or bandwidth described herein.

In some cases, the optical trapping units and electromagnetic delivery units described herein may be integrated into a single optical system. A microscope objective may be used to deliver electromagnetic radiation generated by an electromagnetic delivery unit described herein and to deliver light for trapping atoms generated by an optical trapping unit described herein. Alternatively. or in addition, different objectives may be used to deliver electromagnetic radiation generated by an electromagnetic delivery unit and to deliver light from trapping atoms generated by an optical trapping unit.

The electromagnetic delivery unit(s) may be configured to apply first electromagnetic energy to one or more atoms of the plurality of atoms. Applying the first electromagnetic energy may induce the atoms to adopt one or more superposition states of a first atomic state and a second atomic state that is different from the first atomic state.

The first atomic state may comprise a first single-qubit state. The second atomic state may comprise a second single-qubit state. The first atomic state or second atomic state may be elevated in energy with respect to a ground atomic state of the atoms. The first atomic state or second atomic state may be equal in energy with respect to the ground atomic state of the atoms.

The first atomic state may comprise a first hyperfine electronic state and the second atomic state may comprise a second hyperfine electronic state that is different from the first hyperfine electronic state. For instance, the first and second atomic states may comprise first and second hyperfine states on a multiplet manifold, such as a triplet manifold. The first and second atomic states may comprise first and second hyperfine states, respectively, on a ³P₁ or ³P₂ manifold. The first and second atomic states may comprise first and second hyperfine states, respectively, on a ³P₁ or ³P₂ manifold of any atom described herein, such as a strontium-87 ³P₁ manifold or a strontium-87 ³P₂ manifold.

In some cases, the first and second atomic states are first and second hyperfine states of a first electronic state. Optical excitation may be applied between a first electronic state and a second electronic state. The optical excitation may excite the first hyperfine state and/or the second hyperfine state to the second electronic state. A single-qubit transition may comprise a two-photon transition between two hyperfine states within the first electronic state using a second electronic state as an intermediate state. To drive a single-qubit transition, a pair of frequencies, each detuned from a single-photon transition to the intermediate state, may be applied to drive a two-photon transition. In some cases, the first and second hyperfine states are hyperfine states of the ground electronic state. The ground electronic state may not decay by spontaneous or stimulated emission to a lower electronic state. The hyperfine states may comprise nuclear spin states.

In some cases, the hyperfine states comprise nuclear spin states of a strontium-87 ¹S₀ manifold and the qubit transition drives one or both of two nuclear spin states of strontium-87 ¹S₀ to a state detuned from or within the ³P₂ or ³P₁ manifold. In some cases, the one-qubit transition is a two photon Raman transition between nuclear spin states of strontium-87 ¹S₀ via a state detuned from or within the ³P₂ or ³P₁ manifold. In some cases, the nuclear spin states may be Stark shifted nuclear spin states. A Stark shift may be driven optically. An optical Stark shift may be driven off resonance with any, all, or a combination of a single-qubit transition, a two-qubit transition, a shelving transition, an imaging transition, etc.

In some cases, the hyperfine states comprise nuclear spin states of a ytterbium atom. For example, the one-qubit transition may be nuclear spin states. For example, the one-qubit transition may be a transition between nuclear spin states of ytterbium-171 ¹S₀ coupled from or within the ³P₂ or ³P₁ manifold. In some cases, ytterbium-171 ¹S₀ m_{f}=1/2, −1/2 are coupled to either of ³P₁ m_{f}=3/2, −3/2.

The first atomic state may comprise a first nuclear spin state and the second atomic state may comprise a second nuclear spin state that is different from the first nuclear spin state. The first and second atomic states may comprise first and second nuclear spin states, respectively, of a quadrupolar nucleus. The first and second atomic states may comprise first and second nuclear spin states, respectively, of a spin-1, spin-3/2, spin-2, spin-5/2, spin-3, spin-7/2, spin-4, or spin-9/2 nucleus. The first and second atomic states may comprise first and second nuclear spin states, respectively, of any atom described herein, such as first and second spin states of strontium-87.

For first and second nuclear spin states associated with a nucleus comprising a spin greater than ½ (such as a spin-1, spin-3/2, spin-2, spin-5/2, spin-3, spin-7/2, spin-4, or spin-9/2 nucleus), transitions between the first and second nuclear spin states may be accompanied by transitions between other spin states on the nuclear spin manifold. For instance, for a spin-9/2 nucleus in the presence of a uniform magnetic field, all of the nuclear spin levels may be separated by equal energy. Thus, a transition (such as a Raman transition) designed to transfer atoms from, for instance, an m_{N}=9/2 spin state to an m_{N}=7/2 spin state, may also drive m_{N}=7/2 to m_{N}=5/2, m_{N}=5/2 to m_{N}=3/2, m_{N}=3/2 to m_{N}=1/2, m_{N}=1/2 to m_{N}=−1/2, m_{N}=−1/2 to m_{N}=−3/2, m_{N}=−3/2 to m_{N}=−5/2, m_{N}=−5/2 to m_{N}=−7/2, and m_{N}=−7/2 to m_{N}=−9/2, where m_{N} is the nuclear spin state. Similarly, a transition (such as a Raman transition) designed to transfer atoms from, for instance, an m_{N}=9/2 spin state to an m_{N}=5/2 spin state, may also drive m_{N}=7/2 to m_{N}=3/2, m_{N}=5/2 to m_{N}=1/2, m_{N}=3/2 to m_{N}=−1/2, m_{N}=1/2 to m_{N}=−3/2, m_{N}=−1/2 to m_{N}=−5/2, m_{N}=−3/2 to m_{N}=−7/2, and m_{N}=−5/2 to m_{N}=−9/2. Such a transition may thus not be selective for inducing transitions between particular spin states on the nuclear spin manifold.

It may be desirable to instead implement selective transitions between particular first and second spins states on the nuclear spin manifold. This may be accomplished by providing light from a light source that provides an AC Stark shift and pushes neighboring nuclear spin states out of resonance with a transition between the desired transition between the first and second nuclear spin states. For instance, if a transition from first and second nuclear spin states having m_{N}=−9/2 and m_{N}=−7/2 is desired, the light may provide an AC Stark shift to the m_{N}=−5/2 spin state, thereby greatly reducing transitions between the m_{N}=−7/2 and m_{N}=−5/2 states. Similarly, if a transition from first and second nuclear spin states having m_{N}=−9/2 and m_{N}=−5/2 is desired, the light may provide an AC Stark shift to the m_{N}=−1/2 spin state, thereby greatly reducing transitions between the m_{N}=−5/2 and m_{N}=−1/2 states. This may effectively create a two-level subsystem within the nuclear spin manifold that is decoupled from the remainder of the nuclear spin manifold, greatly simplifying the dynamics of the qubit systems. It may be advantageous to use nuclear spin states near the edge of the nuclear spin manifold (e.g., m_{N}=−9/2 and m_{N}=−7/2, m_{N}=7/2 and m_{N}=9/2, m_{N}=−9/2 and m_{N}=−5/2, or m_{N}=5/2 and m_{N}=9/2 for a spin-9/2 nucleus) such that only one AC Stark shift is required. Alternatively, nuclear spin states farther from the edge of the nuclear spin manifold (e.g., m_{N}=−5/2 and m_{N}=−3/2 or m_{N}=−5/2 and m_{N}=−1/2) may be used and two AC Stark shifts may be implemented (e.g., at m_{N}=−7/2 and m_{N}=−1/2 or m_{N}=−9/2 and m_{N}=3/2).

Qubits based on nuclear spin states in the electronic ground state may allow exploitation of long-lived metastable excited electronic states (such as a ³P₀ state in strontium-87 or a ³P₁ state in ytterbium-171) for qubit storage. Atoms may be selectively transferred into such a state to reduce crosstalk, to improve gate or detection fidelity, or to reduce scattering during atom transfer. Such a storage or shelving process may be atom-selective using the SLMs or AODs described herein. A shelving transition may comprise a transition between the ¹S₀ state in ytterbium-171 to the ³P₀ or ³P₂ state in ytterbium-171. A shelving transition may comprise a transition between the ¹S₀ state in strontium-87 to the ³P₀ or ³P₂ₛₜₐₜₑ in strontium-87.

### Computer Systems

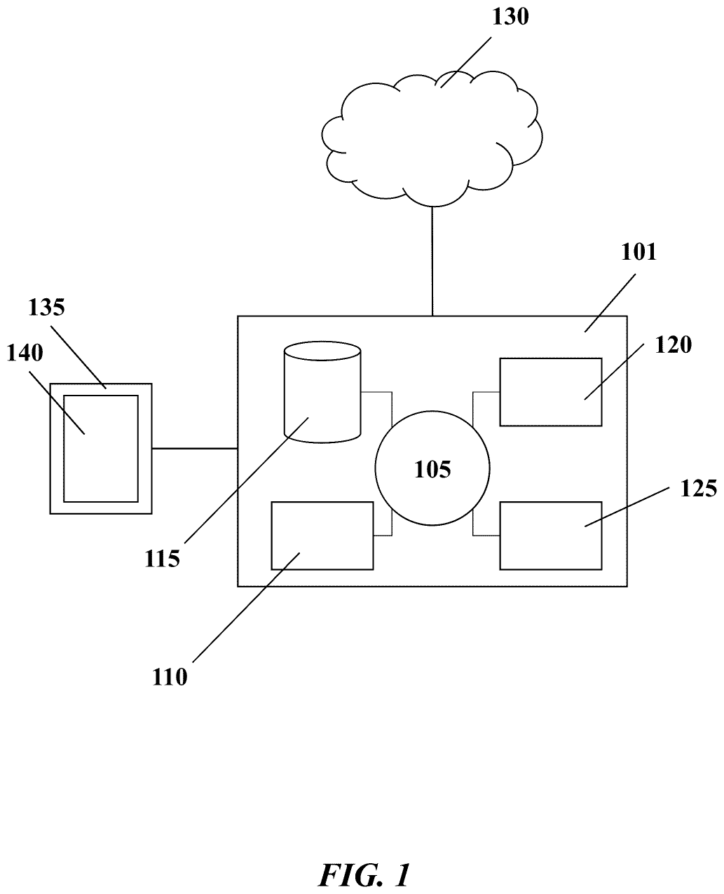

FIG. 1 shows a computer system 101 that is programmed or otherwise configured to operate any method, system, process, or technique described herein (such as system or method for performing a continuous, non-classical computation, described herein). The computer system 101 can regulate various aspects of the present disclosure. The computer system 101 can be an electronic device of a user or a computer system that is remotely located with respect to the electronic device. The electronic device can be a mobile electronic device.

The computer system 101 includes a central processing unit (CPU, also “processor” and “computer processor” herein) 105, which can be a single core or multi core processor, or a plurality of processors for parallel processing. The computer system 101 also includes memory or memory location 110 (e.g., random-access memory, read-only memory, flash memory), electronic storage unit 115 (e.g., hard disk), communication interface 120 (e.g., network adapter) for communicating with one or more other systems, and peripheral devices 125, such as cache, other memory, data storage and/or electronic display adapters. The memory 110, storage unit 115, interface 120 and peripheral devices 125 are in communication with the CPU 105 through a communication bus (solid lines), such as a motherboard. The storage unit 115 can be a data storage unit (or data repository) for storing data. The computer system 101 can be operatively coupled to a computer network (“network”) 130 with the aid of the communication interface 120. The network 130 can be the Internet, an internet and/or extranet, or an intranet and/or extranet that is in communication with the Internet. The network 130 in some cases is a telecommunication and/or data network. The network 130 can include one or more computer servers, which can enable distributed computing, such as cloud computing. The network 130, in some cases with the aid of the computer system 101, can implement a peer-to-peer network, which may enable devices coupled to the computer system 101 to behave as a client or a server.

The CPU 105 can execute a sequence of machine-readable instructions, which can be embodied in a program or software. The instructions may be stored in a memory location, such as the memory 110. The instructions can be directed to the CPU 105, which can subsequently program or otherwise configure the CPU 105 to implement methods of the present disclosure. Examples of operations performed by the CPU 105 can include fetch, decode, execute, and writeback.

The CPU 105 can be part of a circuit, such as an integrated circuit. One or more other components of the system 101 can be included in the circuit. In some cases, the circuit is an application specific integrated circuit (ASIC).

The storage unit 115 can store files, such as drivers, libraries and saved programs. The storage unit 115 can store user data, e.g., user preferences and user programs. The computer system 101 in some cases can include one or more additional data storage units that are external to the computer system 101, such as located on a remote server that is in communication with the computer system 101 through an intranet or the Internet.

The computer system 101 can communicate with one or more remote computer systems through the network 130. For instance, the computer system 101 can communicate with a remote computer system of a user. Examples of remote computer systems include personal computers (e.g., portable PC), slate or tablet PC's (e.g., Apple® iPad, Samsung® Galaxy Tab), telephones. Smart phones (e.g., Apple® iPhone, Android-enabled device, Blackberry®), or personal digital assistants. The user can access the computer system 101 via the network 130.

Methods as described herein can be implemented by way of machine (e.g., computer processor) executable code stored on an electronic storage location of the computer system 101, such as, for example, on the memory 110 or electronic storage unit 115. The machine executable or machine-readable code can be provided in the form of software. During use, the code can be executed by the processor 105. In some cases, the code can be retrieved from the storage unit 115 and stored on the memory 110 for ready access by the processor 105. In some situations, the electronic storage unit 115 can be precluded, and machine-executable instructions are stored on memory 110.

The code can be pre-compiled and configured for use with a machine having a processer adapted to execute the code or can be compiled during runtime. The code can be supplied in a programming language that can be selected to enable the code to execute in a pre-compiled or as-compiled fashion.

Aspects of the systems and methods provided herein, such as the computer system 101, can be embodied in programming. Various aspects of the technology may be thought of as “products” or “articles of manufacture” typically in the form of machine (or processor) executable code and/or associated data that is carried on or embodied in a type of machine-readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine-readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carner wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 101 can include or be in communication with an electronic display 135 that comprises a user interface (UI) 140. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 105.

### EXAMPLES

Example 1: Correction of Atom Loss—In some quantum error correction protocols, the results of a mid-circuit measurement are used to apply conditional operations on qubits. Further, ancilla qubits may generally be reinitialized after being measured. As a proof-of-principle demonstration of these capabilities, we used the results of a mid-circuit measurement to correct for the occasional loss of ancilla qubits while maintaining coherence between data qubits.

For this demonstration, we created a fully filled (above 98% fill probability) 3 by 4 site sub-array by rearranging atoms from a 7 by 10 site array. Individual atoms are moved from filled to empty sites using a single tweezer generated by crossed acousto-optical deflectors (AODs). The subarray was further subdivided into a checkerboard pattern of data and ancilla qubits. Atoms remaining in the outer array formed a reservoir used to refill the ancilla sites.

FIG. 6 shows data relating to conditional reloading of ancilla qubits. Upper panel (a) shows the experimental sequence. During repeated imaging and refilling of ancilla sites, data qubits are protected from decoherence by light-shifts from hiding beams, indicated by shaded boxes. Lower panel (b) shows the contrast on data sites relative to the N=0 case (circles), as well as fill fraction of ancilla sites with (filed diamonds) and without (empty diamonds) conditional reloading. Up to 16 cycles, ancilla filling remains above 98%, and contrast loss per cycle is 0.9(1)% with conditional reloading. Without reloading, ancilla filling drops by 1.1(1)% per cycle.

As shown in detail in FIG. 6, we embedded N repeated cycles of mid-circuit imaging of |1 [symbol] , and rearrangement operations on the ancilla qubits within a Ramsey sequence (two π/2 pulses separated by a time delay) for the data qubits. During optical pumping and imaging, the hiding light was applied to data sites in order to preserve coherence. We applied a single spin-echo pulse after N/2 cycles in order to reduce sensitivity to static differences in the qubit frequencies between sites. Without being limited by theory, differences in the qubit frequencies between the sites may be caused by a gradient in the applied magnetic field. On each cycle, ancilla sites identified as empty in the mid-circuit measurements were refilled with atoms from the reservoir. Optical pumping (OP) of the ancilla qubits after the global π and π/2 pulses served to reset their internal state to |1 [symbol] . Hiding light is applied to the data qubits during optical pumping to prevent decoherence. Optical pumping may require fewer photons to be scattered than imaging does (we use 100 ρs for OP compared to 5 ms for imaging, at similar power levels), and we have observed no impact on data qubit contrast from optical pumping.

By correcting for loss of ancilla atoms, we maintained an ancilla filling fraction of greater than 98% out to 16 imaging and rearrangement cycles, beyond which it slowly drops, which may be due to a lack of reservoir atoms on certain trials. Without correction, the filling dropped by 1.1(1)% per imaging cycle for parameters used in this dataset. Contrast loss per cycle out to 16 cycles is 0.9(1)% for the data qubits, after which point it began to deviate from an exponential decay, which may be due to uncancelled coherent errors. In these sequences, refilling of ancilla states took place within 10-30 ms, with shorter times allotted for higher N to keep the total Ramsey duration to approximately 600 ms.

Example 2: Coherence During MOT Loading—Coherence during reloading may be caused by magnetic field gradients and scattered light from the magneto-optical trap (MOT) used to collect and cool atoms. It may be useful to maintain qubit coherence in order to perform continuous calculations while simultaneously replenishing the reservoir.

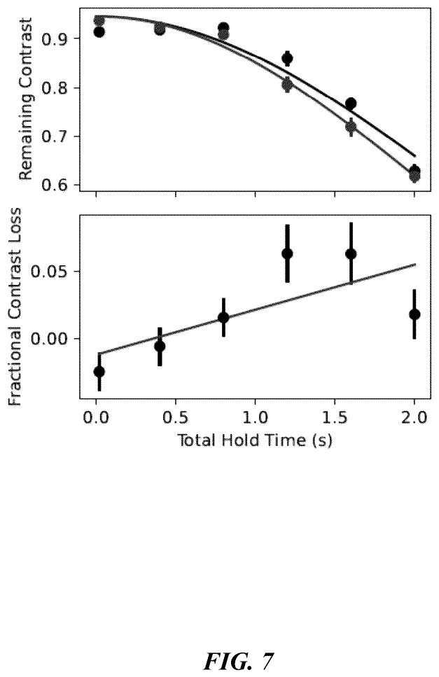

FIG. 7 shows experimental data demonstrating coherence during MOT loading. The upper panel shows the remaining contrast after Ramsey sequence with (grey points) and without (black points) simultaneous MOT operation. A single n pulse in the middle of the hold time was used to eliminate dephasing from static detuning errors. Lines are Gaussian fits, to guide the eye. The lower panel shows relative contrast versus total hold time. A linear fit indicates an additional contrast decay rate of rate of 0.03(2)/s in the presence of the MOT.

In particular, we used an initial MOT operating on the broad ¹S₀ to ¹P₁ transition near 399 nm, which has a greater risk of causing decoherence then the narrow-line MOT that follows (using the narrow ₁S₀ to ³P₁ transition). Our system utilizes a two-chamber design with static magnetic fields, and a 30 cm separation between MOT and science regions. This physical separation allows us to load atoms into the MOT while atoms in the science region remain coherent. We confirmed this by running our standard MOT loading parameters during a Ramsey sequence on the qubits (with a single spin-echo pulse to eliminate the effects of static detuning errors between qubits). From a linear fit to additional contrast loss caused by the MOT, we extracted a decoherence rate of 0.03(2)/s. Our typical broad-line MOT loading lasts for 200 ms. These experiments demonstrate the feasibility of transporting and loading atoms into our science array while retaining qubit coherence.

Experimental set-up—Individual ¹⁷¹Yb atoms were trapped in the sites of an optical tweezer array in the presence of a 500 Gauss magnetic field. Our experimental system consists of two main vacuum regions—the “MOT chamber” and the “science chamber”—connected by a differential pumping tube. Atoms are loaded from a pre-cooled atomic beam into a two-stage magneto-optical trap (formed using the 399 nm ¹P₁ transition followed by the 556 nm ³P₁ narrow-line transition) in the MOT chamber. Atoms are then loaded into an optical lattice formed using 532 nm light and transported vertically by 30 cm into the science chamber. In order to achieve a deep lattice in a power-efficient manner, the waists of the transport beams are translated synchronously with the optical lattice by moving the position of two focusing lenses, one for each of the two counterpropagating beams that form the lattice. Alignment between the two beams is actively maintained using closed-loop piezo-electric steering mirrors. Atoms are transferred into the optical tweezer array by overlapping the atoms with the array, ramping up the power in the tweezers, and then ramping down the transport lattice. This leads to a typical occupancy of several atoms per tweezer. No dissipation is applied to transfer atoms from the transport lattice into the tweezers.

Our two-chamber design allows us to work with temporally static magnetic fields. No magnetic fields were varied during the experimental sequences, which both avoids time-delays associated with switching, and allows us to simultaneously maintain a magnetic field gradient for MOT formation and a large and uniform bias field in our science region. Our two-stage MOT operates at a constant field gradient of approximately 18 Gauss/cm in the strong direction.

After atoms are loaded into tweezers, we apply light with the same parameters as used for imaging of the m_{f}=1/2 qubit state to induce light-assisted collisions and project to a single atom per tweezer. During this time, a second tone that addresses the ¹S₀, m_{f}=−1/2 to ³P₁, m_{f}=1/2 transition is applied to transfer all atoms to the m_{f}=1/2 state.

We address the ¹S₀ to ³P₁ transitions using light derived from a single laser, incident along two counter-propagating paths. Each path has a fiber acousto-optic modulator, which can provide rapid power switching and high extinction. Additionally, each path has a fiber-coupled electro-optic modulator (EOM), which can be used to apply sidebands at frequencies up to several GHz.

Laser beams with opposite circular polarization and different frequencies were applied along the direction of the magnetic field to selectively image the two qubit states ¹S₀ m_{f}=1/2, −1/2 (which we label |1 [symbol] , |0 [symbol] ) by coupling them to either of ³P₁ m_{f}=3/2, −3/2. This provides access to narrow linewidth (˜180 kHz) closed cycling transitions. Scattering from the m_{f}=±1/2 excited states, which would allow population leakage between the qubit states, is suppressed by the large ratio of Zeeman shifts (771 MHz, 681 MHz between the −3/2 and −1/2 states and the 1/2 and 3/2 states, respectively) to transition linewidth. Scattered light is collected by a high-numerical-aperture objective and imaged onto a low-noise camera.

The hiding light is derived from a laser with 459.5960(5) nm wavelength. This wavelength is relatively near-detuned (˜2 nm) from the ³P₁ to 6s6d ³D₁ transition, leading to a ˜9× larger light shift of the ³P₁ state than the ¹S₀ qubit states. Hiding light applies up to 74 MHz differential light-shift with a standard deviation of 6 MHz across sites in the array between the ¹S₀ and ³P₁ manifolds of targeted sites, pushing the imaging light off resonance.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions w % ill now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

What is claimed is:

1. A method for preparing a sample of atoms, the method comprising:
(a) trapping a plurality of atoms in a first array, wherein said first array comprises a first plurality of spatially distinct optical trapping sites;
(b) transferring at least one atom from a second array into said first array to increase a fill factor of said first array, wherein said second array comprises a second plurality of spatially distinct optical trapping sites; and
(c) transferring at least one atom into said second array to increase a fill factor of said second array, wherein at least some of said first plurality of atoms is maintained in said first array during said transferring in (c).

2. The method of claim 1, wherein said transferring in (c) is performed at least partially during said transferring said at least one atom from said second array into said first array in (b).

3. The method of claim 1, further comprising:
repeating (b) and (c) a number of times to maintain a fill factor in said first array.

4. The method of claim 1, further comprising performing a sensing application, a time-keeping operation, or a computation using said at least said first subset of said plurality of atoms.

5. The method of claim 4, wherein said computation is a non-classical computation, and wherein (c) is performed substantially without ending said non-classical computation.

6. The method of claim 5, wherein performing said non-classical computation includes:
applying electromagnetic energy to one or more atoms of said first subset of said plurality of atoms in said first array, thereby inducing said one or more atoms to adopt one or more superposition states of a first atomic state and at least a second atomic state that is different from said first atomic state;
quantum mechanically entangling at least one of said one or more atoms in said one or more superposition states with at least another atom of said first subset of said plurality of atoms in said first array; and
measuring said one or more superposition states to obtain a non-classical result.

7. The method of claim 1, wherein said one or more atoms of said first subset of said plurality of atoms in said one or more superposition states and said at least another atom of said first subset of said plurality of atoms in said first array are quantum mechanically entangled.

8. The method of claim 1, wherein said one or more atoms of said first subset of said plurality of atoms in said one or more superposition states and said at least another atom of said first subset of said plurality of atoms in said first array are in a superposition state with a coherence which is maintained during said transferring in (c).

9. The method of claim 1, wherein said plurality of atoms comprises neutral atoms.

10. The method of claim 1, wherein said plurality of atoms comprises a Group II element or a Group II like element.

11. The method of claim 10, wherein said plurality of atoms comprises an atom with two-valence electrons.

12. The method of claim 11, wherein said plurality of atoms comprises Strontium or Ytterbium.

13. The method of claim 1, wherein one or both of (i) loading said plurality of atoms into said reservoir or (ii) reloading said second array with said additional atoms, is performed using one or both of a moving optical trap or an optical tweezer.

14. The method of claim 1, wherein said first array is distinct from said second array.

15. The method of claim 14, wherein said first array is physically separated from said second array.

16. The method of claim 14, wherein said first array is generated with a first light source and wherein said reservoir is generated with a second light source.

17. The method of claim 1, wherein, subsequent to (a), the method further comprises:
determining an atomic loss number representing a difference between (i) a number of atoms in said plurality of atoms trapped into said first array and (ii) a number of atoms in a remaining subset of said plurality of atoms trapped into said first array that remain in said first array following said performing of at least some of said non-classical computation.

18. The method of claim 17, wherein said at least one atom transferred from said second array into said first array comprise a number of atoms equal to at least said atomic loss number.

19. The method of claim 17, wherein determining said atomic loss number is based on imaging across an imaging axis to determine which sites of said second plurality of spatially distinct optical trapping sites of said first array are occupied.

20. The method of claim 19, wherein:
said first array is physically separated from said second array along an axis perpendicular to said imaging axis; and
one or both of (i) transferring said first subset of said plurality of atoms from said second array into said first array or (ii) transferring said second subset of said plurality of atoms from said second array into said first array, is performed using one or both of a moving optical trap or an optical tweezer.

21. The method of claim 1, wherein both said first array and said second array are one-dimensional, two-dimensional, or three-dimensional.

22. The method of claim 1, wherein said first array has a different number of dimensions than said second array.

23. The method of claim 1, wherein one or both of said first array or said second array are formed using either light or non-optical electromagnetic fields.

24. The method of claim 1, wherein transferring said at least one atom from said second array into said first array comprises:
transferring a first number of atoms from said second array to one or more intermediate arrays, wherein said first number of atoms is at least a subset of said at least one atom, and
transferring a second number of atoms from said one or more intermediate arrays to said first array, wherein said second number of atoms is at most said first number of atoms.

25. The method of claim 24, wherein:
said one or more intermediate arrays includes at least two intermediate arrays; and
at least said second number of atoms are transferred between said at least two intermediate arrays (i) after said first number of atoms are transferred to said at least two intermediate arrays from said second array and (ii) before said second number of atoms are transferred from said at least two intermediate arrays to said first array.

26. The method of claim 1, further comprising:
rearranging, within said first array, positions among said first plurality of spatially distinct optical trapping sites of at least some of one or both of (i) said plurality of atoms in said first array or (ii) said at least one atom in aid first array.
The method of claim 1, wherein said first array is associated with a first spatial light modulator and said second array is associated with a second spatial light modulator.
